(19) United States
(12) Patent Application Publication
(10) Pub. No.: US 2025/0287588 A1
(43) Pub. Date: Sep. 11, 2025

(54) THREE-DIMENSIONAL MEMORY DEVICE INCLUDING MULTI-TIER TRENCH BRIDGE STRUCTURES AND METHODS FOR FORMING THE SAME

(71) Applicant: SANDISK TECHNOLOGIES LLC, ADDISON, TX (US)

(72) Inventors: Atsushi SHIMIZU, Yokkaichi (JP); Wataru MURANAGA, Yokkaichi (JP)

(21) Appl. No.: 18/598,782

(22) Filed: Mar. 7, 2024

(51) Int. Cl. H10B 43/27; H01L 23/00; H01L 25/18; H10B 43/10; H10B 51/10; H10B 51/20; H10B 63/00; H10B 63/10; H10B 80/00

(52) U.S. Cl. CPC H10B 43/27; H10B 43/10; H10B 51/10; H10B 51/20; H10B 63/10; H10B 63/845; H01L 24/08; H01L 25/18; H01L 2224/08145; H01L 2924/1431; H01L 2924/1441; H01L 2924/1443; H01L 2924/14511; H10B 80/00

(57) ABSTRACT

A semiconductor structure includes a first-tier structure containing a pair of first alternating stacks of first insulating layers and first electrically conductive layers, memory openings containing memory opening fill structures vertically extending through the first-tier structure, a lateral isolation cavity located between the pair of first alternating stacks and having a pair of lengthwise sidewalls each having first vertically-straight and laterally-concave surface segments of the first-tier structure that are adjoined to each other at first vertically-extending edges, and perforated first-tier bridge structures containing a different material from the insulating layers located in the lateral isolation cavity.

### FIELD

The present disclosure relates generally to the field of semiconductor devices, and particularly to a three-dimensional memory device including multi-tier trench bridge structures and methods for forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a semiconductor structure comprises: a first-tier structure including a pair of first alternating stacks of first insulating layers and first electrically conductive layers; memory openings vertically extending through the first-tier structure; memory opening fill structures located in the memory openings, wherein each of the memory opening fill structures comprises a vertical semiconductor channel and a memory film; a lateral isolation trench located between the pair of first alternating stacks, and comprising a lateral isolation cavity having a pair of lengthwise sidewalls that laterally extend generally along a first horizontal direction, wherein each lengthwise sidewall of the lateral isolation cavity comprises first vertically-straight and laterally-concave surface segments of the first-tier structure that are adjoined to each other at first vertically-extending edges; and a lateral isolation trench fill structure located in the lateral isolation trench. The lateral isolation trench fill structure comprises: first-tier bridge structures comprising a different material from the insulating layers wherein each of the first-tier bridge structures has a respective set of at least one vertically-extending perforation therethrough; and an insulating spacer continuously extending over sidewalls of the lateral isolation cavity.

According to another aspect of the present disclosure, a method of forming a semiconductor structure comprises: forming a first alternating stack of first insulating layers and first sacrificial material layers; forming first-tier memory openings and first-tier isolation openings through the first alternating stack; forming first sacrificial memory opening fill structures and first-tier sacrificial isolation opening fill structures in the first-tier memory openings and in the first-tier isolation openings, respectively; forming first-tier bridge structures around a subset of the first-tier sacrificial isolation opening fill structures; forming a second alternating stack of second insulating layers and second sacrificial material layers over the first alternating stack; forming second-tier memory openings and second-tier isolation openings through the second alternating stack; removing the first sacrificial memory opening fill structures, wherein memory openings are formed within volumes of the first-tier memory openings and the second-tier memory openings; forming memory opening fill structures in the memory openings, wherein each of the memory opening fill structure comprises a respective vertical semiconductor channel and a vertical memory film; removing the first-tier sacrificial isolation opening fill structures, wherein inter-tier isolation openings are formed within volumes of the first-tier isolation openings and the second-tier isolation openings; and laterally expanding the inter-tier isolation openings to form a lateral isolation cavity by performing a first isotropic etch process which isotropically etches the first alternating stack and the second alternating stack selective to the first-tier bridge structures.

### BRIEF DESCRIPTION OF THE DRAWINGS

FIG. 1 is a schematic vertical cross-sectional view of an exemplary structure for forming a memory die after formation of a first alternating stack of first insulating layers and first sacrificial material layers and a first insulating cap layer over a carrier substrate according to a first embodiment of the present disclosure.

FIG. 2 is a schematic vertical cross-sectional view of the exemplary structure after formation of first stepped surfaces and a first stepped dielectric material portion according to an embodiment of the present disclosure.

FIG. 3A is a schematic vertical cross-sectional view of the exemplary structure after forming first-tier memory openings, first-tier support openings, and first-tier isolation openings according to an embodiment of the present disclosure.

FIG. 3B is a top-down view of the exemplary structure of FIG. 3A. The vertical plane A-A′ is the cut plane of the vertical cross-sectional view of FIG. 3A.

FIG. 4 is a schematic vertical cross-sectional view of the exemplary structure after formation of first-tier sacrificial opening fill material portions according to an embodiment of the present disclosure.

FIG. 5A is a schematic vertical cross-sectional view of the exemplary structure after formation of first-tier bridge cavities according to an embodiment of the present disclosure.

FIG. 5B is a top-down view of the exemplary structure of FIG. 5A. The vertical plane A-A′ is the cut plane of the vertical cross-sectional view of FIG. 5A.

FIG. 6A is a schematic vertical cross-sectional view of the exemplary structure after formation of first-tier bridge structures according to an embodiment of the present disclosure.

FIG. 6B is a top-down view of the exemplary structure of FIG. 6A. The vertical plane A-A′ is the cut plane of the vertical cross-sectional view of FIG. 6A.

FIG. 7 is a schematic vertical cross-sectional view of the exemplary structure after formation of a second alternating stack of second insulating layers and second sacrificial material layers, a second insulating cap layer, second stepped surfaces, and a second stepped dielectric material portion according to an embodiment of the present disclosure.

FIG. 8A is a schematic vertical cross-sectional view of the exemplary structure after formation of second-tier sacrificial opening fill material portions and second-tier bridge structures according to an embodiment of the present disclosure.

FIG. 8B is a top-down view of the exemplary structure of FIG. 8A. The vertical plane A-A′ is the cut plane of the vertical cross-sectional view of FIG. 8A.

FIG. 9A is a schematic vertical cross-sectional view of the exemplary structure after formation of a third alternating stack of third insulating layers and third sacrificial material layers, a third insulating cap layer, third stepped surfaces, a third stepped dielectric material portion, third-tier sacrificial opening fill material portions, and third-tier bridge structures according to an embodiment of the present disclosure.

FIG. 9B is a top-down view of the exemplary structure of FIG. 9A. The vertical plane A-A′ is the cut plane of the vertical cross-sectional view of FIG. 9A.

FIG. 10 is a schematic vertical cross-sectional view of the exemplary structure after formation of inter-tier support openings according to an embodiment of the present disclosure.

FIG. 11 is a schematic vertical cross-sectional view of the exemplary structure after formation of support pillar structures according to an embodiment of the present disclosure.

FIG. 12 is a schematic vertical cross-sectional view of the exemplary structure after formation of inter-tier memory openings according to an embodiment of the present disclosure.

FIGS. 13A-13D are sequential vertical cross-sectional views of a region around an multi-tier memory opening during formation of a memory opening fill structure according to an embodiment of the present disclosure.

FIG. 14A is a vertical cross-sectional view of the exemplary structure after formation of memory opening fill structures according to an embodiment of the present disclosure.

FIG. 14B is a top-down view of the exemplary structure of FIG. 14A. The vertical plane A-A′ is the cut plane of the vertical cross-sectional view of FIG. 14A.

FIG. 15A is a vertical cross-sectional view of the exemplary structure after formation and patterning of a contact-level dielectric layer and contact-level openings according to an embodiment of the present disclosure.

FIG. 15B is a top-down view of the exemplary structure of FIG. 15A. The hinged vertical plane A-A′ is a cut plane of the vertical cross-sectional view of FIG. 15A.

FIG. 16A is a vertical cross-sectional view of the exemplary structure after formation of inter-tier isolation openings according to an embodiment of the present disclosure.

FIG. 16B is a top-down view of the exemplary structure of FIG. 16A. The hinged vertical plane A-A′ is a cut plane of the vertical cross-sectional view of FIG. 16A.

FIG. 17A is a vertical cross-sectional view of the exemplary structure after formation of lateral isolation trenches according to an embodiment of the present disclosure.

FIG. 17B is a horizontal cross-sectional view of the exemplary structure along the horizontal plane B-B′ of FIG. 17A. The hinged vertical plane A-A′ is a cut plane of the vertical cross-sectional view of FIG. 17A.

FIG. 17C is a horizontal cross-sectional view of the exemplary structure along the horizontal plane C-C′ of FIG. 17A. The hinged vertical plane A-A′ is a cut plane of the vertical cross-sectional view of FIG. 17A.

FIG. 17D is a horizontal cross-sectional view of the exemplary structure along the horizontal plane D-D′ of FIG. 17A. The hinged vertical plane A-A′ is a cut plane of the vertical cross-sectional view of FIG. 17A.

FIG. 17E is a vertical cross-sectional view of the exemplary structure along the vertical plane E-E′ of FIG. 17B according to an embodiment of the present disclosure.

FIG. 18A is a vertical cross-sectional view of the exemplary structure after formation of laterally-extending cavities according to an embodiment of the present disclosure.

FIG. 18B is a horizontal cross-sectional view of the exemplary structure along the horizontal plane B-B′ of FIG. 18A. The hinged vertical plane A-A′ is a cut plane of the vertical cross-sectional view of FIG. 18A.

FIG. 19A is a vertical cross-sectional view of the exemplary structure after formation of electrically conductive layers according to an embodiment of the present disclosure.

FIG. 19B is a top-down view of the exemplary structure of FIG. 19A. The hinged vertical plane A-A′ is a cut plane of the vertical cross-sectional view of FIG. 19A.

FIG. 20A is a vertical cross-sectional view of the exemplary structure after formation of lateral isolation trench fill structures according to an embodiment of the present disclosure.

FIG. 20B is a horizontal cross-sectional view of the exemplary structure along the horizontal plane B-B′ of FIG. 20A. The hinged vertical plane A-A′ is a cut plane of the vertical cross-sectional view of FIG. 20A.

FIG. 20C is a horizontal cross-sectional view of the exemplary structure along the horizontal plane C-C′ of FIG. 20A. The hinged vertical plane A-A′ is a cut plane of the vertical cross-sectional view of FIG. 20A.

FIG. 20D is a horizontal cross-sectional view of the exemplary structure along the horizontal plane D-D′ of FIG. 20A. The hinged vertical plane A-A′ is a cut plane of the vertical cross-sectional view of FIG. 20A.

FIG. 20E is a vertical cross-sectional view of the exemplary structure along the vertical plane E-E′ of FIG. 20B according to an embodiment of the present disclosure.

FIG. 21 is a vertical cross-sectional view of the exemplary structure after formation of various contact via structures according to an embodiment of the present disclosure.

FIG. 22 is a vertical cross-sectional view of the exemplary structure after formation of memory-side dielectric material layers and memory-side metal interconnect structures to form a memory die, and after attaching a logic die to the memory die according to an embodiment of the present disclosure.

FIG. 23 is a vertical cross-sectional view of the exemplary structure after removal of a carrier substrate and formation of source layers according to an embodiment of the present disclosure.

FIGS. 24-31 are vertical cross-sectional views of alternative configurations of the exemplary structures according to various embodiments of the present disclosure.

### DETAILED DESCRIPTION

As discussed above, the embodiments of the present disclosure are directed to a three-dimensional memory device including multi-tier trench bridge structures and methods for forming the same, of which various aspects are now described in detail. Embodiments of the disclosure can be employed to form semiconductor devices, such as three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

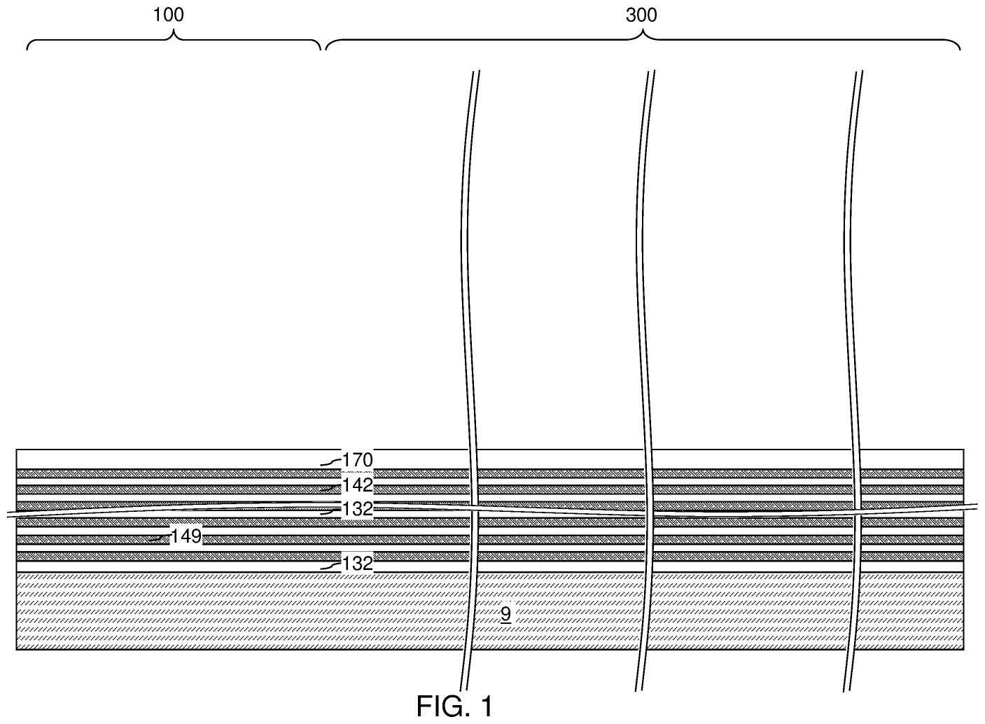

Referring to FIG. 1, an exemplary structure according to an embodiment of the present disclosure is illustrated. The exemplary structure comprises base material layer over which layer stacks are subsequently formed. In one embodiment, the base material layer comprises a carrier substrate 9, which may be a semiconductor substrate. For example, the carrier substrate 9 may comprise a commercially available silicon wafer. Alternatively, the carrier substrate 9 may comprise any material that may be removed selective the materials of overlying materials which are subsequently formed.

A first alternating stack of first insulating layers 132 and first spacer material layers can be formed over the carrier substrate 9. In one embodiment, the first spacer material layers may comprise first sacrificial material layers 142. In this case, a first alternating stack (132, 142) of first insulating layers 132 and first sacrificial material layers 142 can be formed over the carrier substrate 9. The first insulating layers 132 comprise an insulating material, such as undoped silicate glass (i.e., silicon oxide) or a doped silicate glass, and the first sacrificial material layers 142 comprise a sacrificial material, such as silicon nitride or silicon-germanium. In one embodiment, the first insulating layers 132 may comprise silicon oxide layers, and the first sacrificial material layers 142 may comprise silicon nitride layers. The first alternating stack (132, 142) may comprise multiple repetitions of a unit layer stack including a first insulating layer 132 and a first sacrificial material layer 142. The total number of repetitions of the unit layer stack within the first alternating stack (132, 142) may be, for example, in a range from 8 to 1,024, such as from 32 to 256, although lesser and greater number of repetitions may also be employed.

Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed.

A first insulating cap layer 170 can be formed over the first alternating stack (132, 142). In one embodiment, the first insulating cap layer 170 has a homogeneous material composition throughout. In one embodiment, the first insulating cap layer 170 comprises, and/or consists essentially of, a dielectric material selected from undoped silicate glass and a doped silicate glass. In one embodiment, the first insulating cap layer 170 may have a thickness in a range from 60 nm to 400 nm, such as from 100 nm to 300 nm, although lesser and greater thicknesses may also be employed.

The first insulating cap layer 170 may be formed by chemical vapor deposition. In one embodiment, the first insulating cap layer 170 comprises a silicon oxide material formed by decomposition of a precursor material (such as tetraethylorthosilicate (TEOS)) for silicon oxide deposition. In one embodiment, the first insulating cap layer 170 may include residual carbon atoms and/or residual hydrogen atoms. In one embodiment, the carbon concentration in the first insulating cap layer 170 may be in a range from 2 parts per million to 5,000 parts per million, such as from 10 parts per million to 1,000 parts per million. In one embodiment, the hydrogen concentration in the first insulating cap layer 170 may be in a range from 100 parts per million to 10,000 parts per million, such as from 300 parts per million to 5,000 parts per million.

The exemplary structure comprises a memory array region 100 in which a three-dimensional array of memory elements is to be subsequently formed, and a contact region 300 in which layer contact via structures contacting word lines are to be subsequently formed.

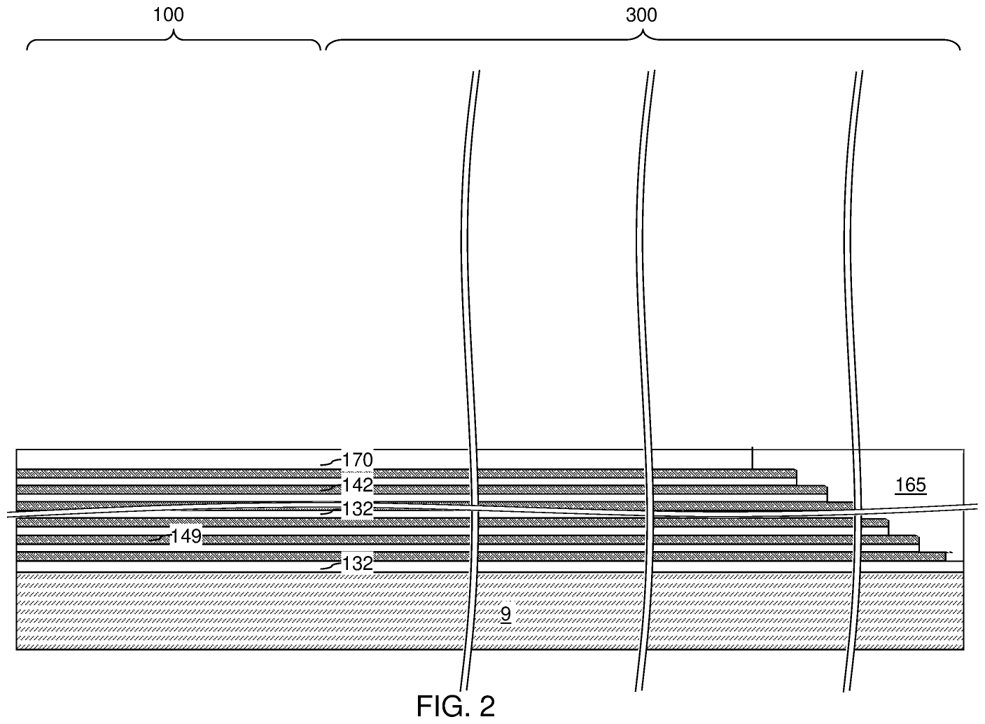

Referring to FIG. 2, first stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first alternating stack (132, 142) and the first insulating cap layer 170 are removed through formation of the first stepped surfaces. A “stepped cavity” refers to a cavity having stepped surfaces.

The first stepped cavity can have various first stepped surfaces such that the horizontal cross-sectional shape of the first stepped cavity changes in steps as a function of the vertical distance from the top surface of the carrier substrate 9. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the first alternating stack (132, 142) laterally extends farther than any overlying first sacrificial material layer 142 within the first alternating stack (132, 142) in the terrace region. The first stepped surfaces of the first alternating stack (132, 142) continuously extend from a bottommost layer within the first alternating stack (132, 142) to the first insulating cap layer 170. Generally, the first stepped surfaces continuously extend from a bottommost layer within the first alternating stack (132, 142) at least to a topmost layer within the first alternating stack (132, 142).

A first stepped dielectric material portion 165 (i.e., an insulating fill material portion) can be formed in the first stepped cavity by deposition of a dielectric material therein. For example, a dielectric material such as silicon oxide can be deposited in the first stepped cavity. Excess portions of the deposited dielectric material can be removed from above the top surface of the first insulating cap layer 170, for example, by chemical mechanical planarization (CMP). The remaining portion of the deposited dielectric material filling the first stepped cavity constitutes the first stepped dielectric material portion 165. As used herein, a “stepped” element refers to an element that has first stepped surfaces and a horizontal cross-sectional area that increases monotonically as a function of a vertical distance from a top surface of a substrate on which the element is present. If silicon oxide is employed for the first stepped dielectric material portion 165, the silicon oxide of the first stepped dielectric material portion 165 may, or may not, be doped with dopants such as B, P, and/or F. In one embodiment, the first stepped dielectric material portion 165 overlies and contacts the first stepped surfaces, and has a top surface that is coplanar with the top surface of the first insulating cap layer 170.

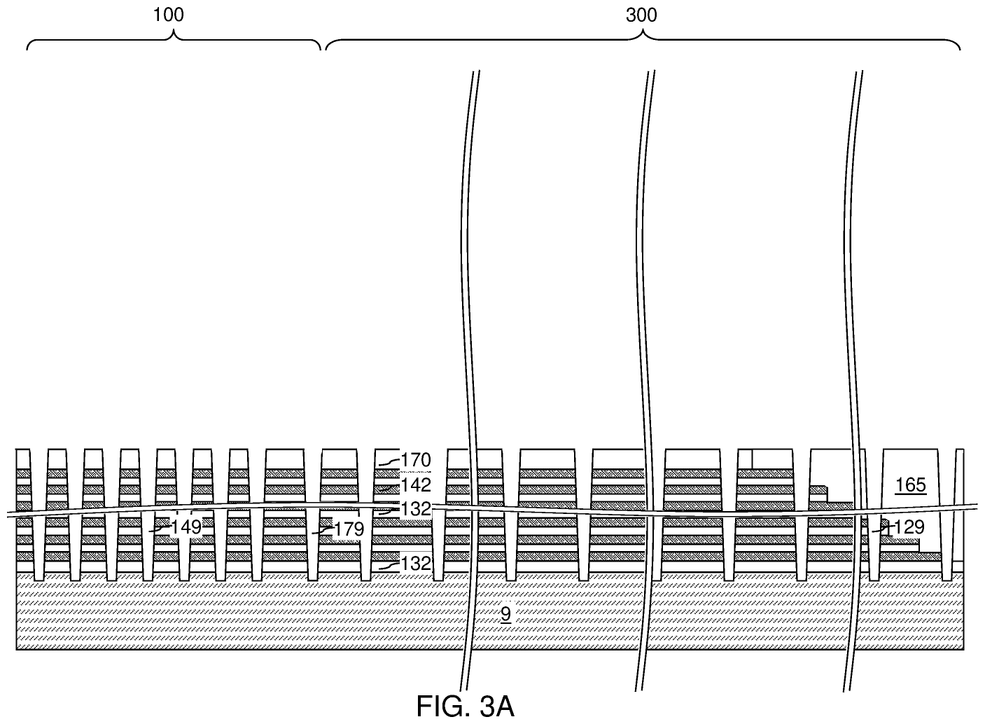

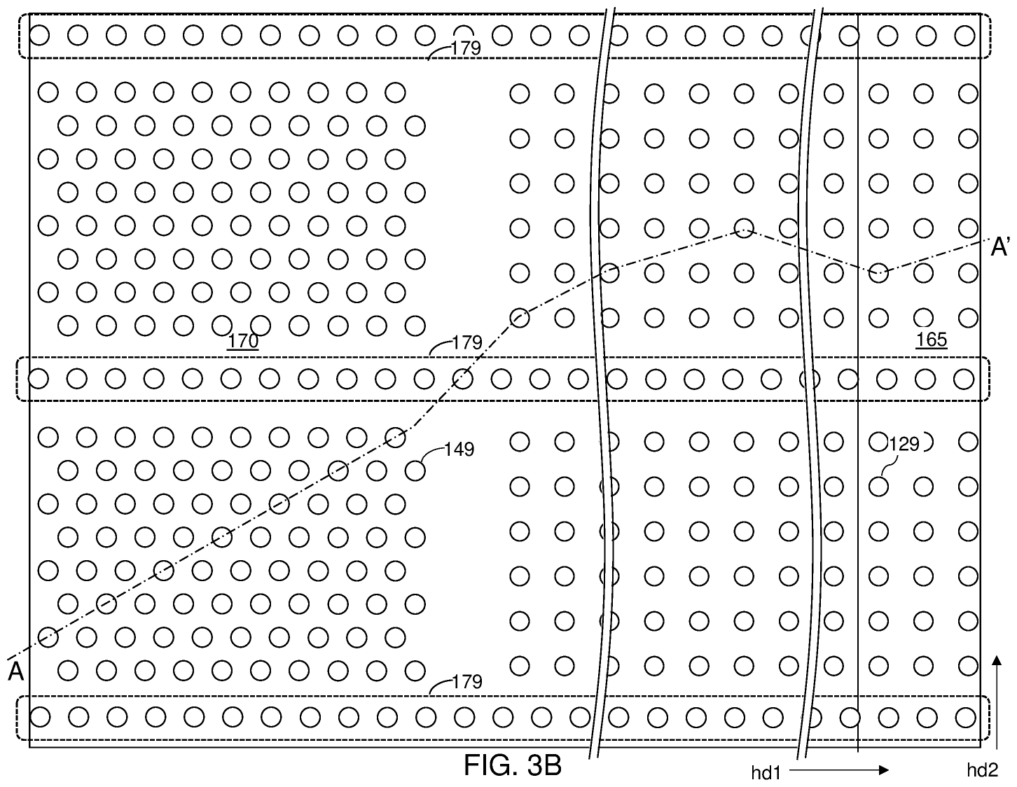

Referring to FIGS. 3A and 3B, a first etch mask layer (not shown) can be formed over the first insulating cap layer 170. The first etch mask layer may comprise a carbon-based material such as amorphous carbon or diamond-like carbon. A photoresist layer (not shown) can be formed above the first etch mask layer, and can be lithographically patterned to form various openings therein. A first anisotropic etch process can be performed to transfer the pattern of the openings in the photoresist layer through the first etch mask layer, the first insulating cap layer 170, and an upper portion of the combination of the first alternating stack (132, 142) and the first stepped dielectric material portion 165. The various openings may comprise first-tier memory openings 149 that are formed in the memory array region 100, first-tier support openings 129 that are formed in the contact region 300, and optionally first-tier lateral isolation openings 179 that laterally extend along a first horizontal direction hd1 across the memory array region 100 and the contact region 300. Each of the first-tier memory openings 149, the first-tier support openings 129, and the first-tier lateral isolation openings 179 can vertically extend through the first alternating stack (132, 142). Alternatively, the first-tier lateral isolation openings 179 can be formed separately from the first-tier memory openings 149 and the first-tier support openings 129, during a separate photolithography and etching steps.

The first-tier support openings 129 may have a maximum diameter in a range from 50 nm to 400 nm, such as from 70 nm to 300 nm, although lesser and greater maximum diameters may be employed. The first-tier memory openings 149 may have a maximum diameter in a range from 50 nm to 400 nm, such as from 70 nm to 300 nm, although lesser and greater maximum diameters may be employed. The first-tier lateral isolation openings 179 may have a width in a range from 150 nm to 600 nm, such as from 200 nm to 400 nm, although lesser and greater widths may also be employed. Each of the first-tier memory openings 149, the first-tier support openings 129, and the first-tier lateral isolation openings 179 may have a respective tapered sidewall such that an upper portion has a greater lateral dimension (such as a diameter) than a lower portion.

In one embodiment, the memory array region 100 may be laterally spaced apart from the contact region 300 along a first horizontal direction hd1. The first-tier memory openings 149 may comprise rows of first-tier memory openings 149 that are arranged along the first horizontal direction hd1 and laterally spaced apart along a second horizontal direction hd2 that is perpendicular to the first horizontal direction hd2. Multiple clusters of first-tier memory openings 149, each containing a respective two-dimensional periodic array of first-tier memory openings 149, may be formed in the memory array region 100. The clusters of first-tier memory openings 149 may be laterally spaced apart along the second horizontal direction hd2. The first-tier lateral isolation openings 179 may be formed as rows of first-tier lateral isolation openings 179. Each row of first-tier lateral isolation openings 179 may be arranged along the first horizontal direction hd1.

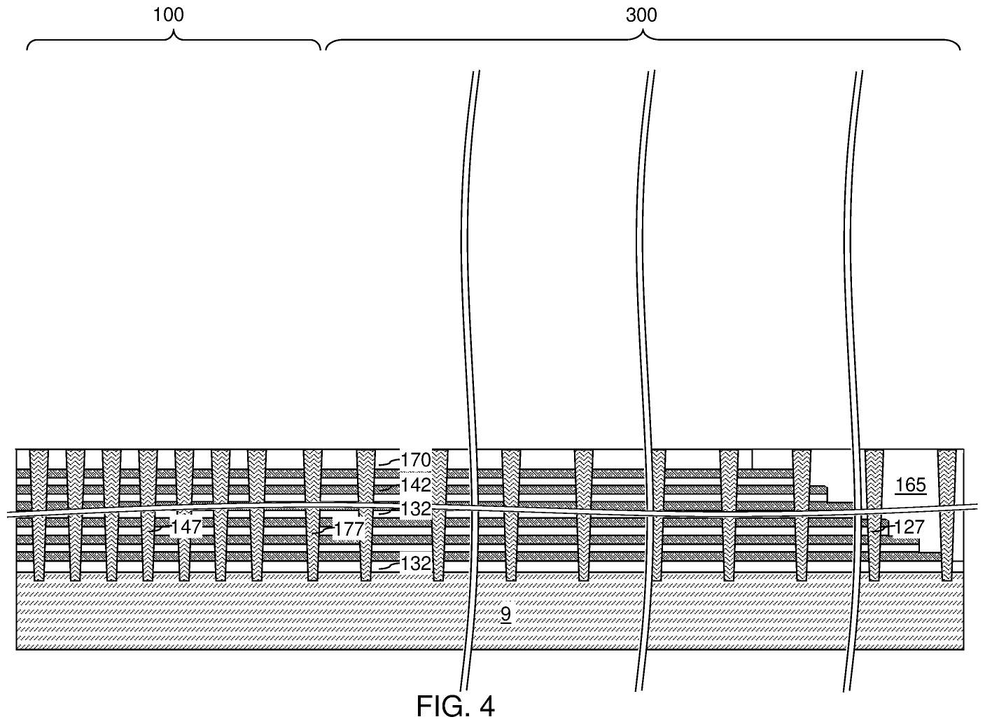

Referring to FIG. 4, an optional etch stop liner (not shown) and a first sacrificial fill material can be deposited in the first-tier memory openings 149, the first-tier support openings 129, and the first-tier lateral isolation openings 179. The optional etch stop liner (if present) comprises a thin silicon oxide layer having a thickness in a range from 1 nm to 6 nm. The first sacrificial fill material may comprise a carbon-based material, such as amorphous carbon or diamond-like carbon.

The first etch mask layer can be removed selective to the material of the first insulating cap layer 170. A planarization process can be performed to remove portions of the first sacrificial fill material from above the horizontal plane including the top surface of the first insulating cap layer 170. Remaining portions of the first sacrificial fill material that fill the first-tier memory openings 149, the first-tier support openings 129, and the first-tier lateral isolation openings 179 constitute first-tier sacrificial opening fill material portions (147, 127, 177). The first-tier sacrificial opening fill material portions (147, 127, 177) comprise first-tier sacrificial memory opening fill material portions 147 that are formed in the first-tier memory openings 149, first-tier sacrificial support opening fill material portions 127 that are formed in the first-tier support openings 129, and first-tier sacrificial isolation opening fill material portions 177 that are formed in the first-tier lateral isolation openings 179.

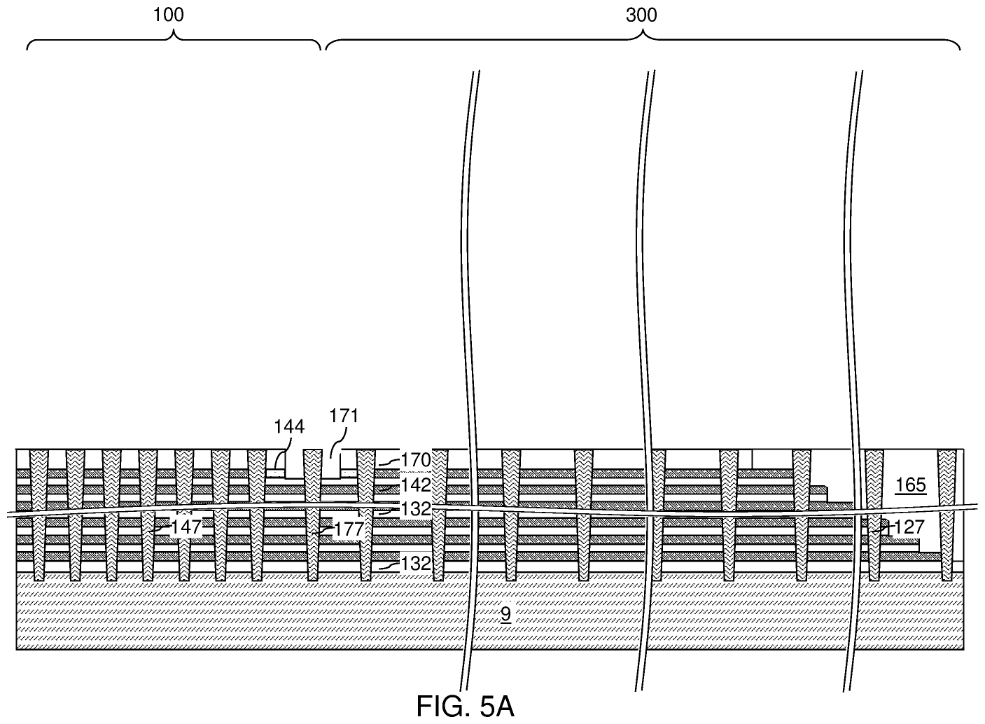

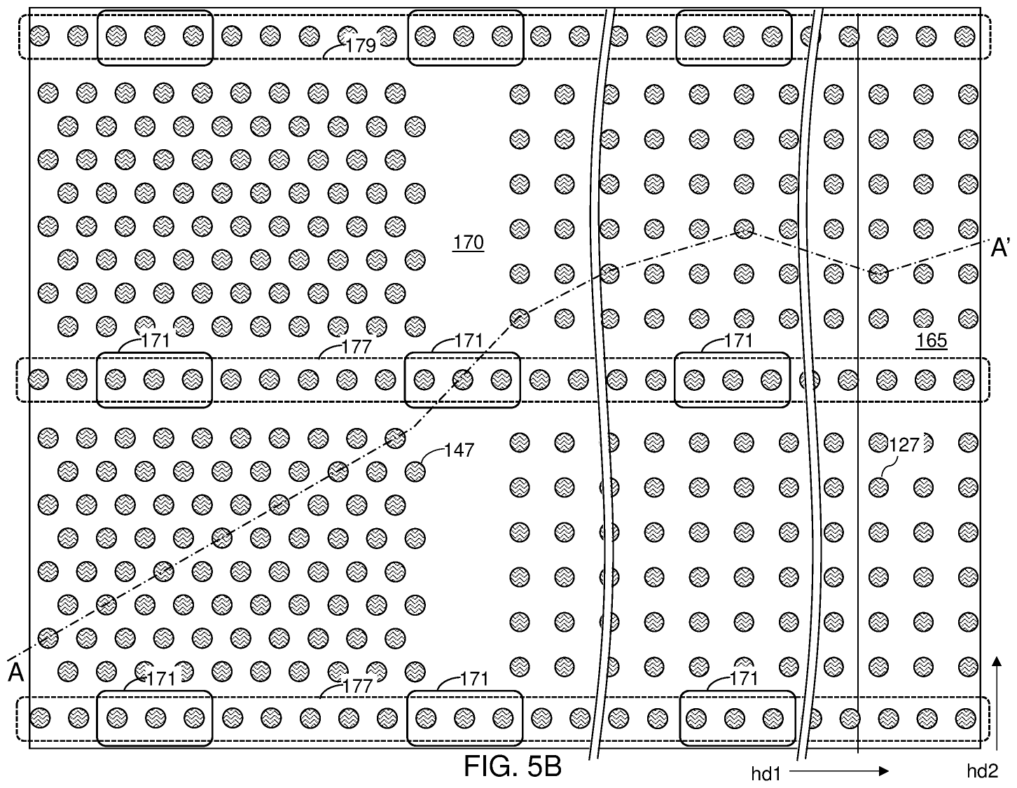

Referring to FIGS. 5A and 5B, a photoresist layer (not shown) can be applied over the first insulating cap layer 170, and can be lithographically patterned to form discrete openings overlying a respective subset of the first-tier sacrificial isolation opening fill material portions 177. Each discrete opening may have a periphery that encloses a respective subset of the first-tier sacrificial isolation opening fill material portions 177 in a plan view. In the illustrated example, each discrete opening may enclose a respective set of three first-tier sacrificial isolation opening fill material portions 177 in the plan view. However, each discrete opening may enclose less than three or more than three of the first-tier sacrificial isolation opening fill material portions 177.

A selective anisotropic etch process can be performed to etch the materials of the first insulating cap layer 170, the first sacrificial material layers 142, and the first insulating layers 132 selective to the material of the first-tier sacrificial isolation opening fill material portions 177. In an illustrative example, if the first insulating cap layer 170 and the first insulating layers 132 comprise silicon oxide, if the first sacrificial material layers 142 comprise silicon nitride, and if the first-tier sacrificial isolation opening fill material portions 177 comprise amorphous carbon, a reactive ion etch process employing a mixture of CF₄ and CHF₃ can be performed to etch the materials of the first insulating cap layer 170, the first sacrificial material layers 142, and the first insulating layers 132 selective to the material of the first-tier sacrificial isolation opening fill material portions 177.

Cavities, which are herein referred to as first-tier bridge cavities 171, are formed in the volumes from which materials of the first insulating cap layer 170, the first sacrificial material layers 142, and the first insulating layers 132 are removed. Each first-tier bridge cavity 171 laterally surrounds upper portions of a respective set of first-tier sacrificial isolation opening fill material portions 177. While an embodiment is illustrated in FIG. 5B in which each first-tier bridge cavity 171 laterally surrounds three of the first-tier sacrificial isolation opening fill material portions 177, in an alternative embodiment, each first-tier bridge cavity 171 may laterally surround less than three or more than three of the first-tier sacrificial isolation opening fill material portions 177. The bottom surface of each first-tier bridge cavity 171 may be formed at the level of the first insulating cap layer 170, or may be formed at the level of one of the first sacrificial material layers 142 or one of the first insulating layers 132. In one embodiment, the bottom surface of each first-tier bridge cavity 171 may be formed at the level below the topmost first sacrificial material layer 142 or below the N-th first sacrificial material layer 142 from the top, where N is an integer from 2 to 10. The height of the first-tier bridge cavities 171 may be in a range from 0.5% to 10% of the thickness of a first tier structure, which is the sum of the thickness of the first alternating stack (132, 142) and the thickness of the first insulating cap layer 170.

In one embodiment, the portions of the first sacrificial material layers 142 which are exposed in the first-tier bridge cavities 171 are oxidized to form first lateral fin spacers 144 which extend laterally from the sidewalls of the first-tier bridge cavities 171 and contact the remaining portions of the first sacrificial layers 142. The oxidation may comprise a plasma and/or thermal oxidation in an oxygen containing ambient (e.g., in oxygen gas, air or nitrous oxide N₂O ambient). If the first sacrificial material layers 142 comprise silicon nitride, then the first lateral fin spacers 144 comprise silicon oxide or silicon oxynitride.

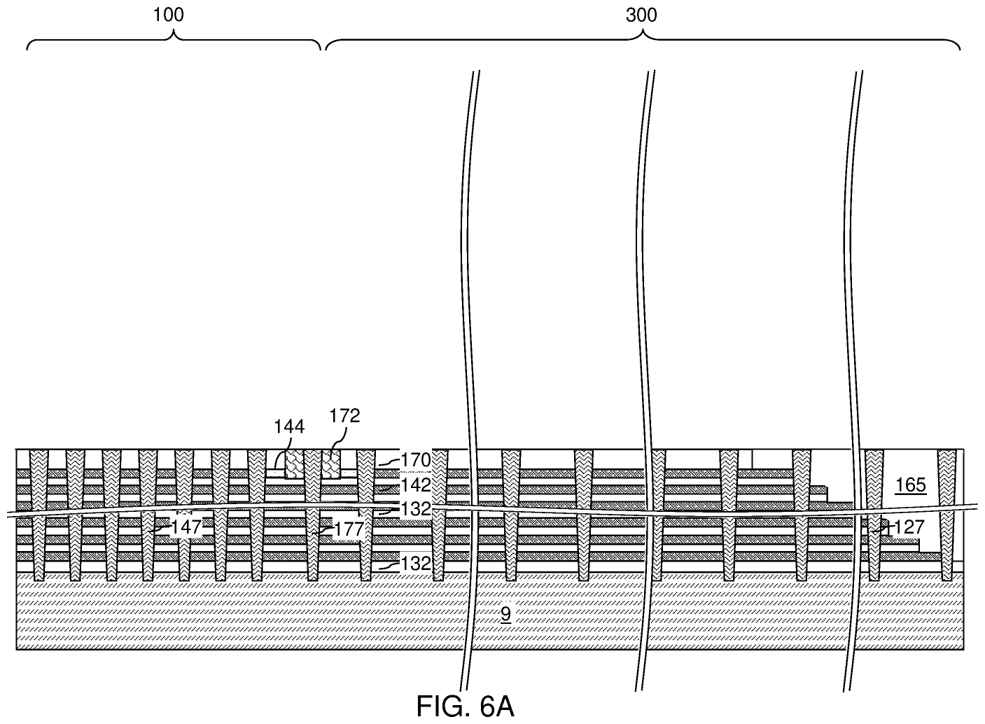

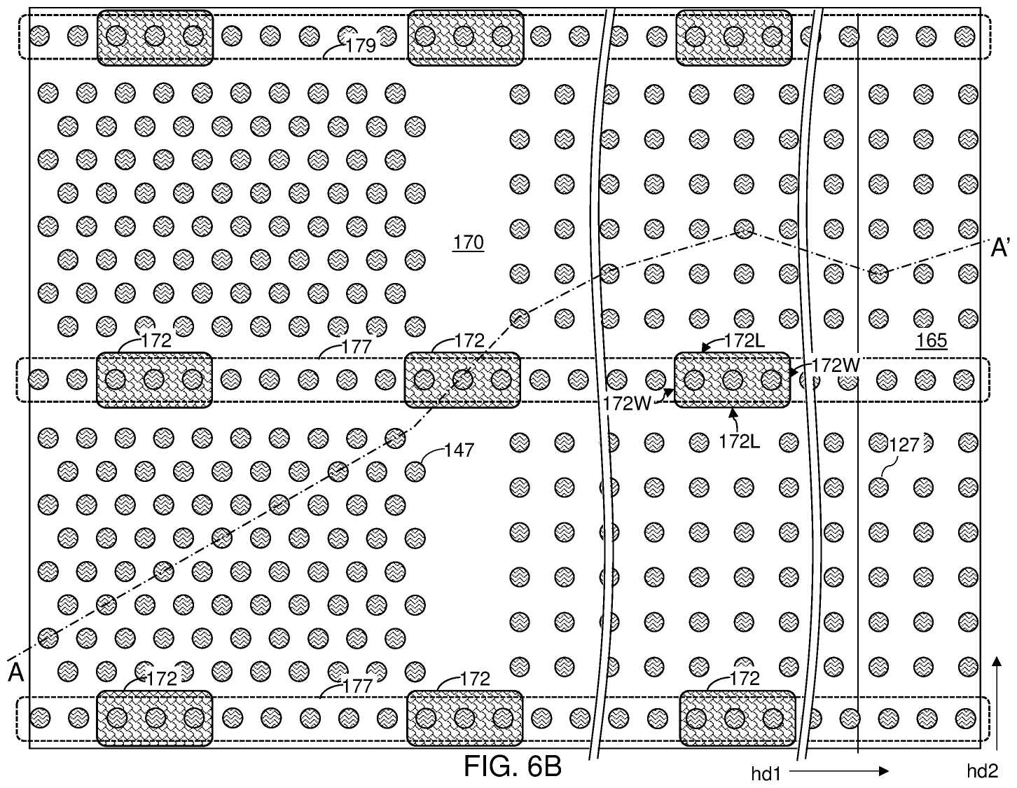

Referring to FIGS. 6A and 6B, a first cavity fill material can be deposited in the first-tier bridge cavities 171. The first cavity fill material comprises a material that is different from the materials of the first alternating stack (132,142) and the first-tier sacrificial isolation opening fill material portions 177. For example, the first cavity fill material may comprise a semiconductor material, such as amorphous silicon or polysilicon. Excess portions of the first cavity fill material can be removed from above the horizontal plane including the top surface of the first insulating cap layer 170 by performing a planarization process, which may comprise a chemical mechanical polishing process and/or a recess etch process. Each remaining portion of the first cavity fill material that fills a respective one of the first-tier bridge cavities 171 constitutes a first-tier bridge structure 172. In one embodiment, top surface of the first-tier bridge structures 172 may be coplanar with the top surface of the first insulating cap layer 170, i.e., may be formed within the horizontal plane including the top surface of the first insulating cap layer 170. Generally, the first-tier bridge structures 172 surround a subset of the first-tier sacrificial isolation opening fill structures 177. While an embodiment is illustrated in FIG. 6B in which each first-tier bridge structure 172 laterally surrounds three of the first-tier sacrificial isolation opening fill material portions 177, in an alternative embodiment, each first-tier bridge structure 172 may laterally surround less than three or more than three of the first-tier sacrificial isolation opening fill material portions 177. In one embodiment shown in FIG. 6B, each first-tier bridge structures 172 comprises a pair of lengthwise sidewalls 172L that laterally extend along the first horizontal direction (e.g., word line direction) hd1, and a pair of widthwise sidewalls 172W that laterally extend along the second horizontal direction (e.g., bit line direction) hd2, which may be perpendicular to the first horizontal direction hd1. Each first-tier bridge structure 172 contacts cylindrical surface segments of a subset of the first-tier sacrificial isolation opening fill structures 177, and has a top surface within a same horizontal plane as top surfaces of the first-tier sacrificial isolation opening fill structures 177. The first lateral fin spacers 144 prevent contact between the first-tier bridge structure 172 and the first sacrificial material layers 142.

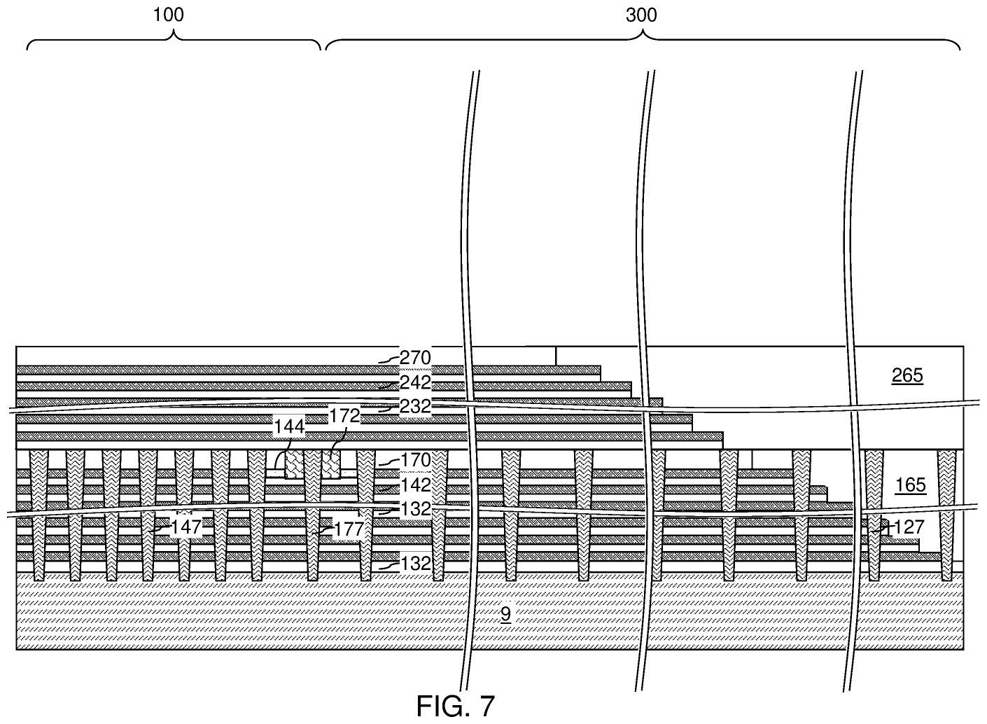

Referring to FIG. 7, the processing steps described with reference to FIGS. 1 and 2 can optionally be performed with any needed changes to form a second alternating stack of second insulating layers 232 and second sacrificial material layers 242, a second insulating cap layer 270, second stepped surfaces, and a second stepped dielectric material portion 265. The second stepped surfaces may be laterally offset relative to the first stepped surfaces toward the memory array region 100.

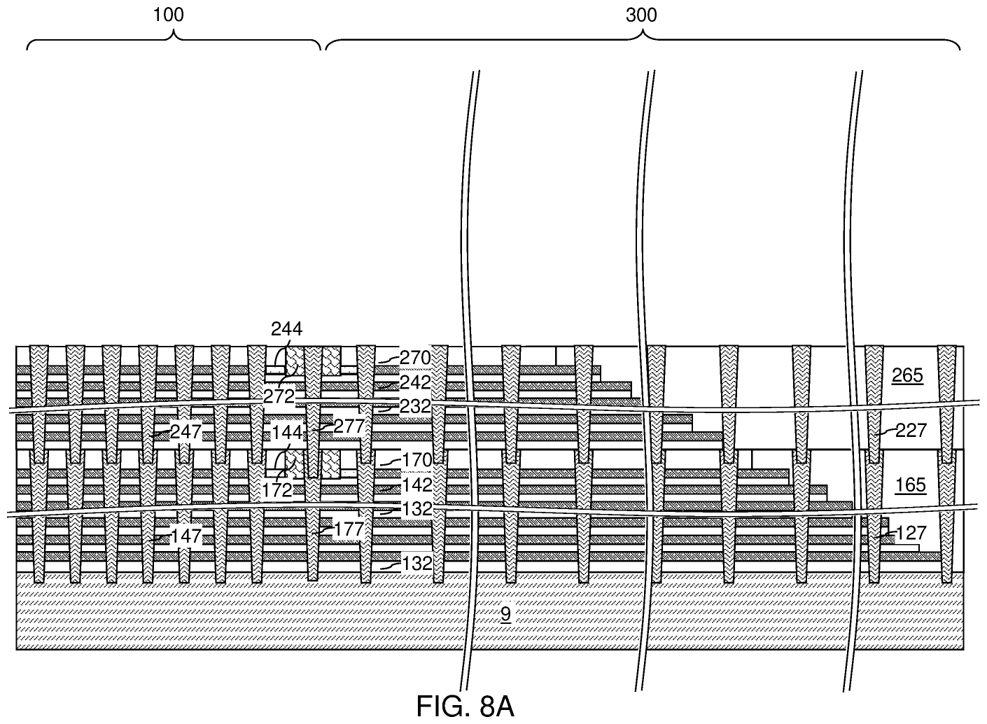

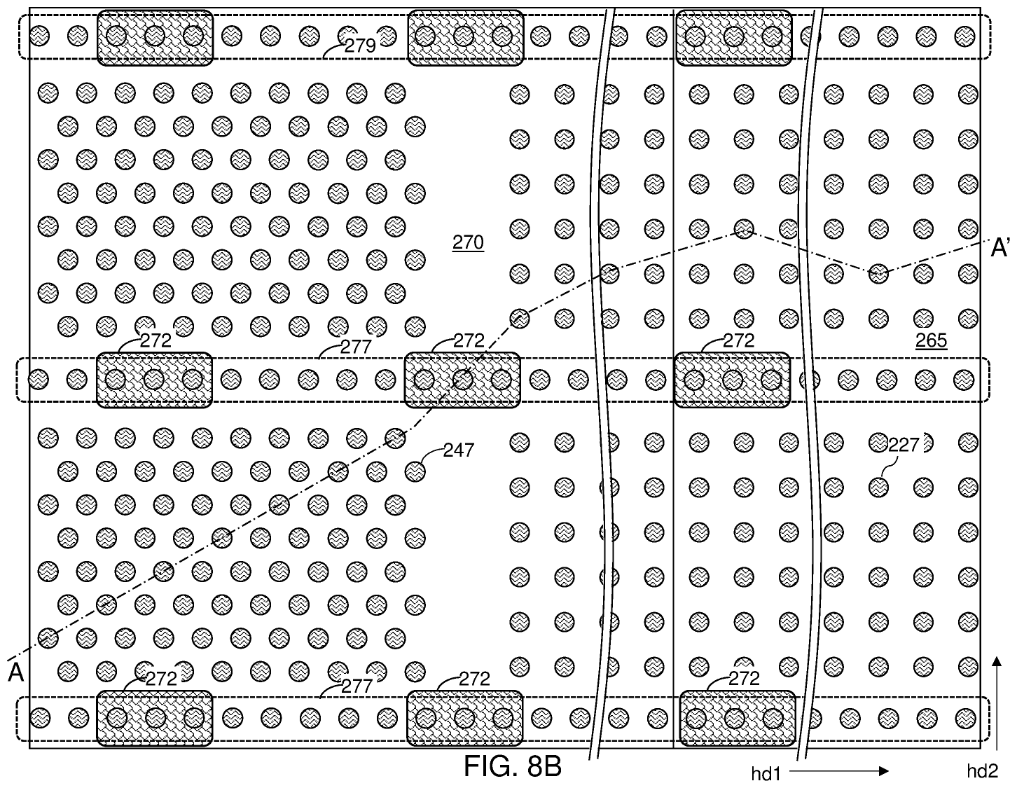

Referring to FIGS. 8A and 8B, the processing steps described with reference to FIGS. 3A-6B can be performed with any needed changes to form second-tier openings, second-tier sacrificial opening fill material portions (247, 227, 277), second lateral fin spacers 244 and second-tier bridge structures 272. The second-tier sacrificial opening fill material portions (247, 227, 277) may comprise second-tier sacrificial memory opening fill material portions 247 that are formed in the second-tier memory openings, second-tier sacrificial support opening fill material portions 227 that are formed in the second-tier support openings, and second-tier sacrificial isolation opening fill material portions 277 that are formed in the second-tier lateral isolation openings.

Second-tier bridge cavities can be formed above the areas of the first-tier bridge structures 172 in a top-down view. In other words, the areas of the second-tier bridge cavities may be the same as the areas of the first-tier bridge structures 172 in the top-down view. A second cavity fill material can be deposited in the second-tier bridge cavities. The second cavity fill material comprises a material that is different from the materials of the second alternating stack (232, 242) and the second-tier sacrificial isolation opening fill material portions 277. For example, the second cavity fill material may comprise a semiconductor material, such as amorphous silicon or polysilicon. Excess portions of the second cavity fill material can be removed from above the horizontal plane including the top surface of the second insulating cap layer 270 by performing a planarization process, which may comprise a chemical mechanical polishing process and/or a recess etch process. Each remaining portion of the second cavity fill material that fills a respective one of the second-tier bridge cavities constitutes a second-tier bridge structure 272. In one embodiment, the top surfaces of the second-tier bridge structures 272 may be coplanar with the top surface of the second insulating cap layer 270, i.e., may be formed within the horizontal plane including the top surface of the second insulating cap layer 270. The second-tier bridge structures 272 can be formed around a subset (e.g., less than three, exactly three, or more than three) of the second-tier sacrificial isolation opening fill structures 277. In one embodiment, each second-tier bridge structure 272 comprises a pair of lengthwise sidewalls that laterally extend along the first horizontal direction hd1, and a pair of widthwise sidewalls that laterally extend along the second horizontal direction hd2, which may be perpendicular to the first horizontal direction hd1. Each second-tier bridge structure 272 contacts cylindrical surface segments of the subset of the second-tier sacrificial isolation opening fill structures 277, and has a top surface within a same horizontal plane as top surfaces of the second-tier sacrificial isolation opening fill structures 277.

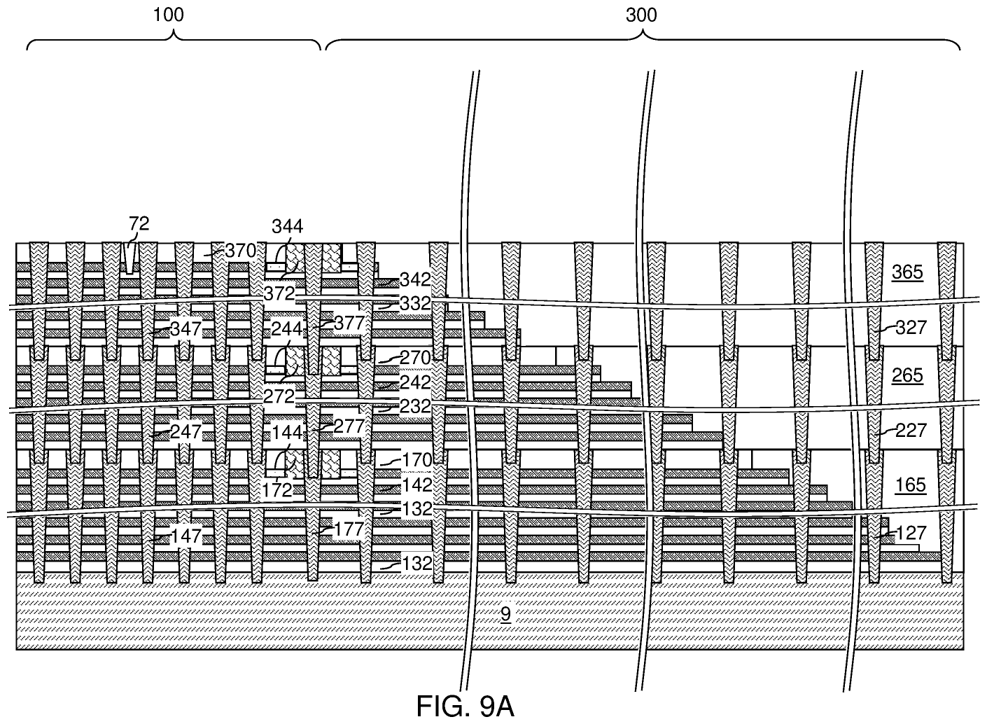

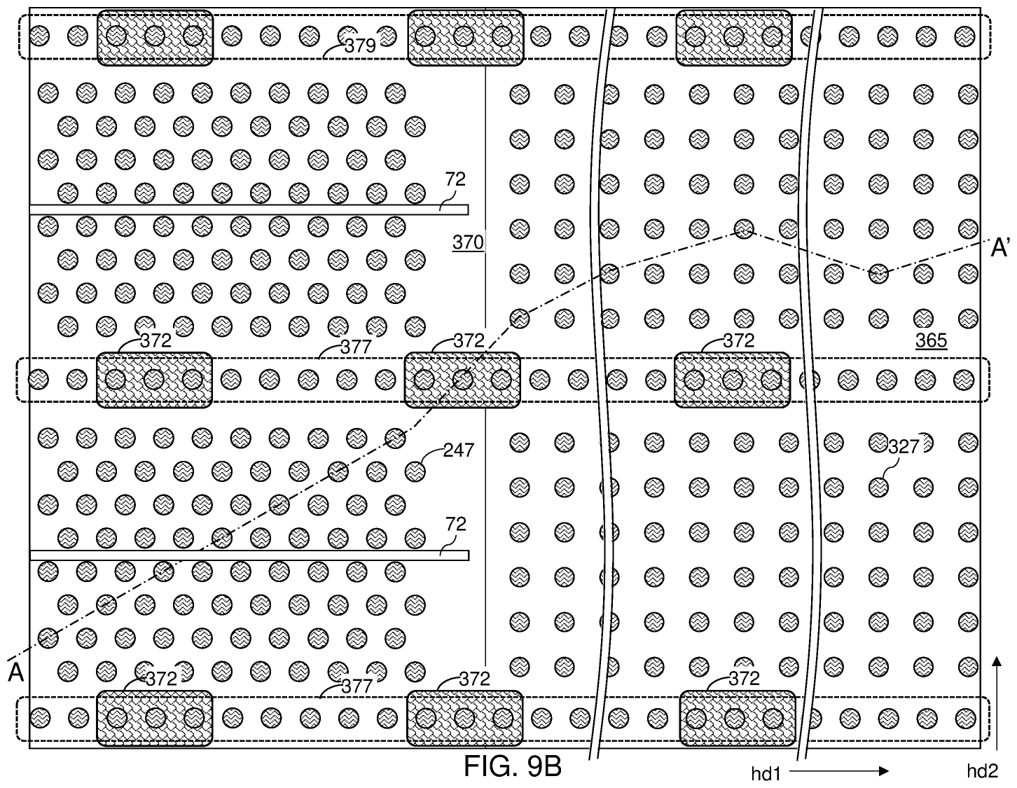

Referring to FIGS. 9A and 9B, the processing steps described with reference to FIGS. 1 and 2 can optionally be performed with any needed changes to form a third alternating stack of third insulating layers 332 and third sacrificial material layers 342, a third insulating cap layer 370, third stepped surfaces, and a third stepped dielectric material portion 365. The third stepped surfaces may be laterally offset relative to the second stepped surfaces toward the memory array region 100.

The processing steps described with reference to FIGS. 3A-6B can be performed with any needed changes to form third-tier openings, third-tier sacrificial opening fill material portions (347, 327, 377), third lateral fin spacers 344, and third-tier bridge structures 372. The third-tier sacrificial opening fill material portions (347, 327, 377) may comprise third-tier sacrificial memory opening fill material portions 347 that are formed in the third-tier memory openings, third-tier sacrificial support opening fill material portions 327 that are formed in the third-tier support openings, and third-tier sacrificial isolation opening fill material portions 377 that are formed in the third-tier lateral isolation openings.

Third-tier bridge cavities can be formed above the areas of the second-tier bridge structures 272 in a top-down view. In other words, the areas of the third-tier bridge cavities may be the same as the areas of the second-tier bridge structures 272 in the top-down view. A third cavity fill material can be deposited in the third-tier bridge cavities. The third cavity fill material comprises a material that is different from the materials of the third alternating stack (332, 342) and the third-tier sacrificial isolation opening fill material portions 377. For example, the third cavity fill material may comprise a semiconductor material, such as amorphous silicon or polysilicon. Excess portions of the third cavity fill material can be removed from above the horizontal plane including the top surface of the third insulating cap layer 370 by performing a planarization process, which may comprise a chemical mechanical polishing process and/or a recess etch process. Each remaining portion of the third cavity fill material that fills a respective one of the third-tier bridge cavities constitutes a third-tier bridge structure 372. In one embodiment, the top surfaces of the third-tier bridge structures 372 may be coplanar with the top surface of the third insulating cap layer 370, i.e., may be formed within the horizontal plane including the top surface of the third insulating cap layer 370. The third-tier bridge structures 372 can be formed around a subset (e.g., less than three, exactly three, or more than three) of the third-tier sacrificial isolation opening fill structures 377. In one embodiment, each third-tier bridge structure 372 comprises a pair of lengthwise sidewalls that laterally extend along the first horizontal direction hd1, and a pair of widthwise sidewalls that laterally extend along the second horizontal direction hd2, which may be perpendicular to the first horizontal direction hd1. Each third-tier bridge structure 372 contacts cylindrical surface segments of a subset of the third-tier sacrificial isolation opening fill structures 377, and has a top surface within a same horizontal plane as top surfaces of the third-tier sacrificial isolation opening fill structures 377. Drain-select-level isolation structures (e.g., silicon oxide filled trenches) 72 laterally extending along a first horizontal direction hd1 may be formed through a subset of the uppermost third sacrificial material layers 342 that will be replaced with drain side select gate electrodes.

While an embodiment memory device is illustrated with three tiers, in alternative embodiments, there may be one tier, two tiers or more than three tiers. Furthermore, while an embodiment is illustrated in which each tier includes a respective bridge structure, in alternative embodiments, the bridge structure may be omitted in one or more tiers. For example, in a three tier memory device, the third-tier bridge structure 372 may be omitted. In a two tier memory device, the second-tier bridge structure 272 may be omitted.

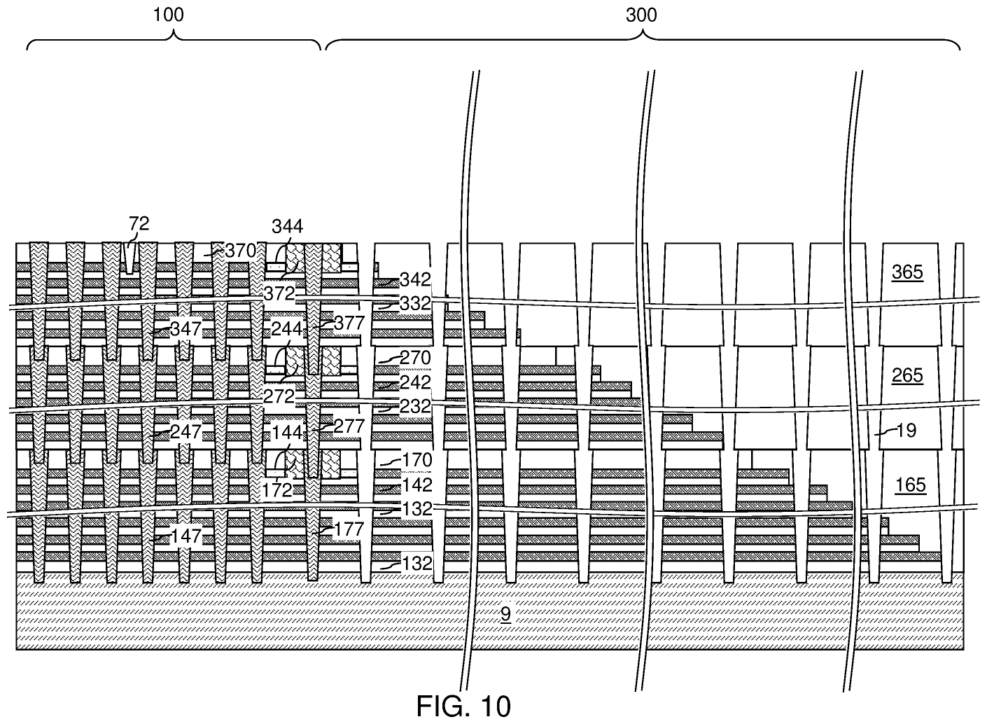

Referring to FIG. 10, a photoresist layer (not shown) can be applied over the third insulating cap layer 170 and the third stepped dielectric material portion 365, and can be lithographically patterned to cover the third-tier sacrificial memory opening fill material portions 347 and the third-tier sacrificial isolation opening fill material portions 377 without covering the third-tier sacrificial support opening fill material portions 327. An ashing process can be performed to remove the various sacrificial support opening fill material portions (327, 227, 127). Inter-tier support openings 19, which are also referred to as support openings 19, can be formed in the volumes from which the materials of the sacrificial support opening fill material portions (327, 227, 127) are removed.

Each of the inter-tier support openings 19 comprises a first tapered sidewall vertically extending through the first-tier structure, a second tapered sidewall vertically extending through the second-tier structure, a third tapered sidewall vertically extending through the third-tier structure, a first annular planar surface located within a first horizontal plane including a topmost surface of the first-tier structure and having an inner periphery that is adjoined to a bottom periphery of the second tapered sidewall and having an outer periphery that is adjoined to a top periphery of the first tapered sidewall, and a second annular planar surface located within a second horizontal plane including a topmost surface of the second-tier structure and having an inner periphery that is adjoined to a bottom periphery of the third tapered sidewall and having an outer periphery that is adjoined to a top periphery of the second tapered sidewall.

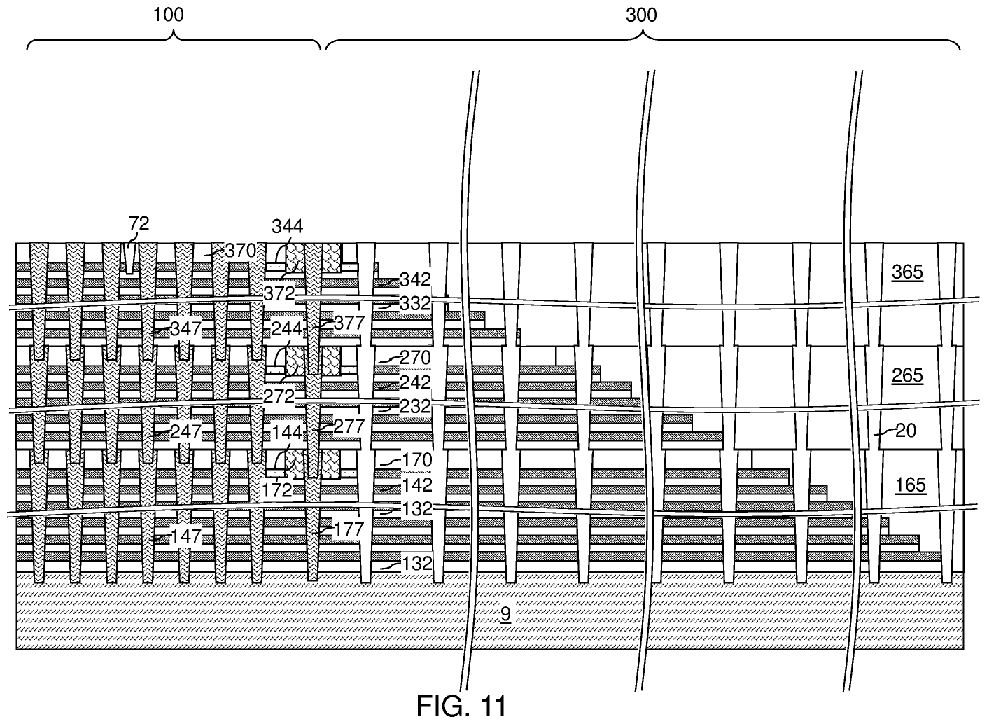

Referring to FIG. 11, a dielectric fill material, such as undoped silicate glass (e.g., silicon oxide) or a doped silicate glass can be conformally deposited in the inter-tier support openings 19. Excess portions of the dielectric fill material can be removed from above the third horizontal plane including the topmost surface of the third insulating cap layer 370 by performing a planarization process. The planarization process may comprise a chemical mechanical polishing process and/or a recess etch process. Each remaining portion of the dielectric fill material filling a respective inter-tier support opening 19 constitutes a dielectric pillar structure 20.

Each of the dielectric pillar structures 20 comprises a first tapered sidewall vertically extending through the first-tier structure, an optional second tapered sidewall vertically extending through the second-tier structure, an optional third tapered sidewall vertically extending through the third-tier structure, a first annular planar surface located within a first horizontal plane including a topmost surface of the first-tier structure and having an inner periphery that is adjoined to a bottom periphery of the second tapered sidewall and having an outer periphery that is adjoined to a top periphery of the first tapered sidewall, and an optional second annular planar surface located within a second horizontal plane including a topmost surface of the second-tier structure and having an inner periphery that is adjoined to a bottom periphery of the third tapered sidewall and having an outer periphery that is adjoined to a top periphery of the second tapered sidewall.

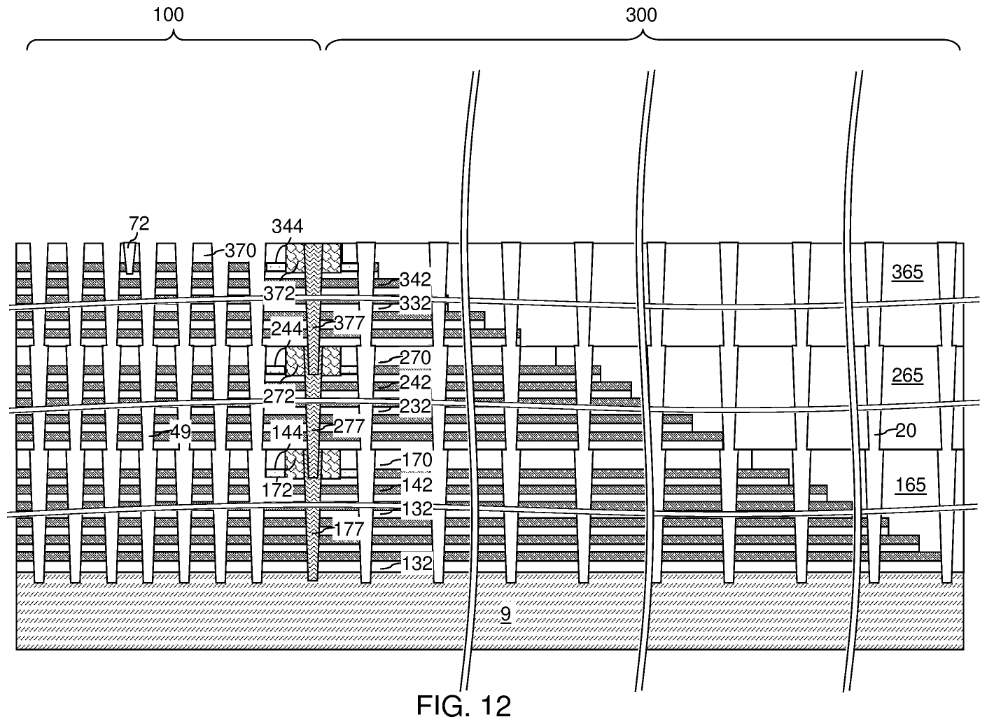

Referring to FIG. 12, a photoresist layer (not shown) can be applied over the third insulating cap layer 170 and the third stepped dielectric material portion 365, and can be lithographically patterned to cover the third-tier sacrificial isolation opening fill material portions 377 without covering the third-tier sacrificial memory opening fill material portions 347. An ashing process can be performed to remove the various sacrificial memory opening fill material portions (347, 247, 147). Inter-tier memory openings 49, which are also referred to as memory openings 49, can be formed in the volumes from which the materials of the sacrificial memory opening fill material portions (347, 247, 147) are removed. The memory openings 49 are formed by forming voids within volumes of the first-tier memory openings 149, the optional second-tier memory openings, and the optional third-tier memory openings.

Each of the inter-tier memory openings 49 comprises a first tapered sidewall vertically extending through the first-tier structure, an optional second tapered sidewall vertically extending through the second-tier structure, an optional third tapered sidewall vertically extending through the third-tier structure, a first annular planar surface located within a first horizontal plane including a topmost surface of the first-tier structure and having an inner periphery that is adjoined to a bottom periphery of the second tapered sidewall and having an outer periphery that is adjoined to a top periphery of the first tapered sidewall, and an optional second annular planar surface located within a second horizontal plane including a topmost surface of the second-tier structure and having an inner periphery that is adjoined to a bottom periphery of the third tapered sidewall and having an outer periphery that is adjoined to a top periphery of the second tapered sidewall.

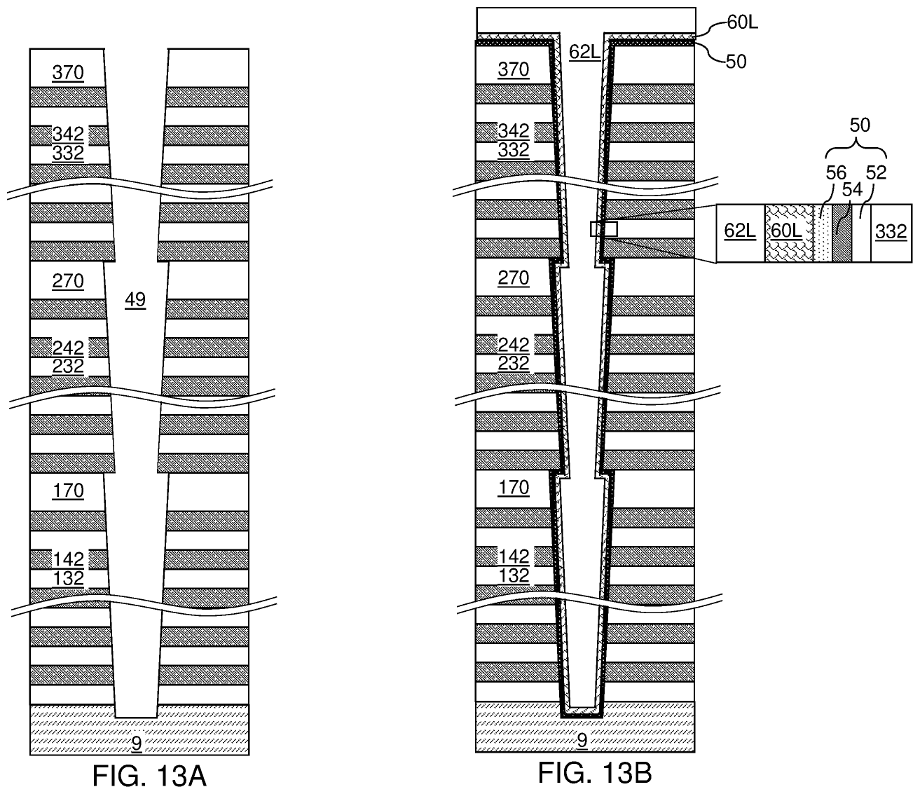

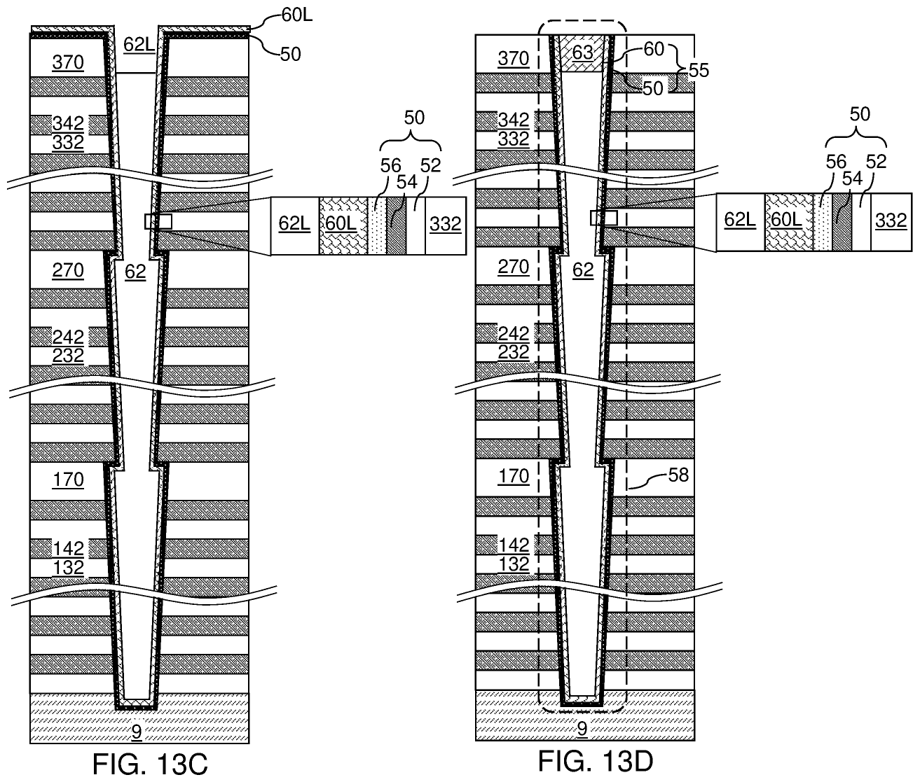

FIGS. 13A-13D are sequential vertical cross-sectional views of a region around an multi-tier memory opening during formation of a memory opening fill structure according to an embodiment of the present disclosure.

Referring to FIG. 13A, a memory opening 49 is illustrated after the processing steps of FIG. 12. Referring to FIG. 13B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material (e.g., silicon oxide) can be deposited in remaining volumes of the memory openings 49 and over the alternating stack (32, 42).

Referring to FIG. 13C, the dielectric core layer 62L can be vertically recessed such that each remaining portion of the dielectric core layer 62L has a top surface at, or about, the horizontal plane including the bottom surface of the insulating cap layer 370. Each remaining portion of the dielectric core layer 62L constitutes a dielectric core 62.

Referring to FIG. 13D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon. Excess portions of the deposited semiconductor material having a doping of the second conductivity type and a horizontal portion of the semiconductor channel layer 60L can be removed from above the horizontal plane including the top surface of the insulating cap layer 370, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

In an alternative embodiment, the inter-tier support openings 19 and the memory openings 49 may be formed during the same step by removing the sacrificial support opening fill material portions (327, 227, 127) and the sacrificial memory opening fill material portions (347, 247, 147) at the same time. In this embodiment, the inter-tier support openings 19 and the memory openings 49 are filled with the same set of materials during the same deposition and patterning steps shown in FIGS. 13A-13D. In this embodiment, the support pillar structures 20 comprise dummy memory opening fill structures which have the same composition as the memory opening fill structures 58, but which are not electrically connected to respective bit lines.

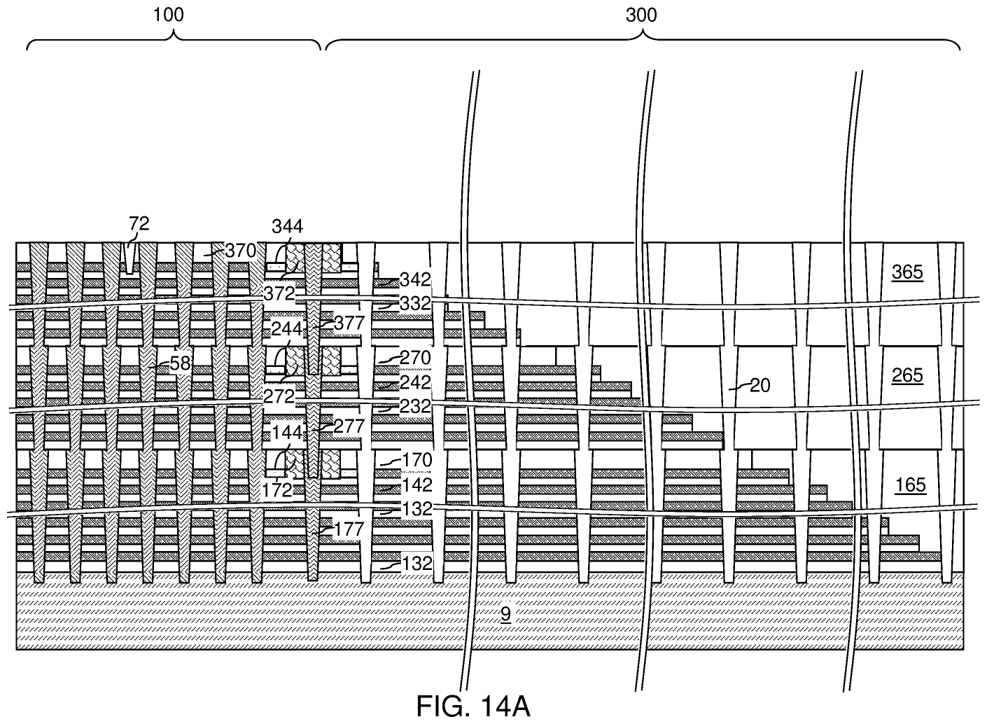

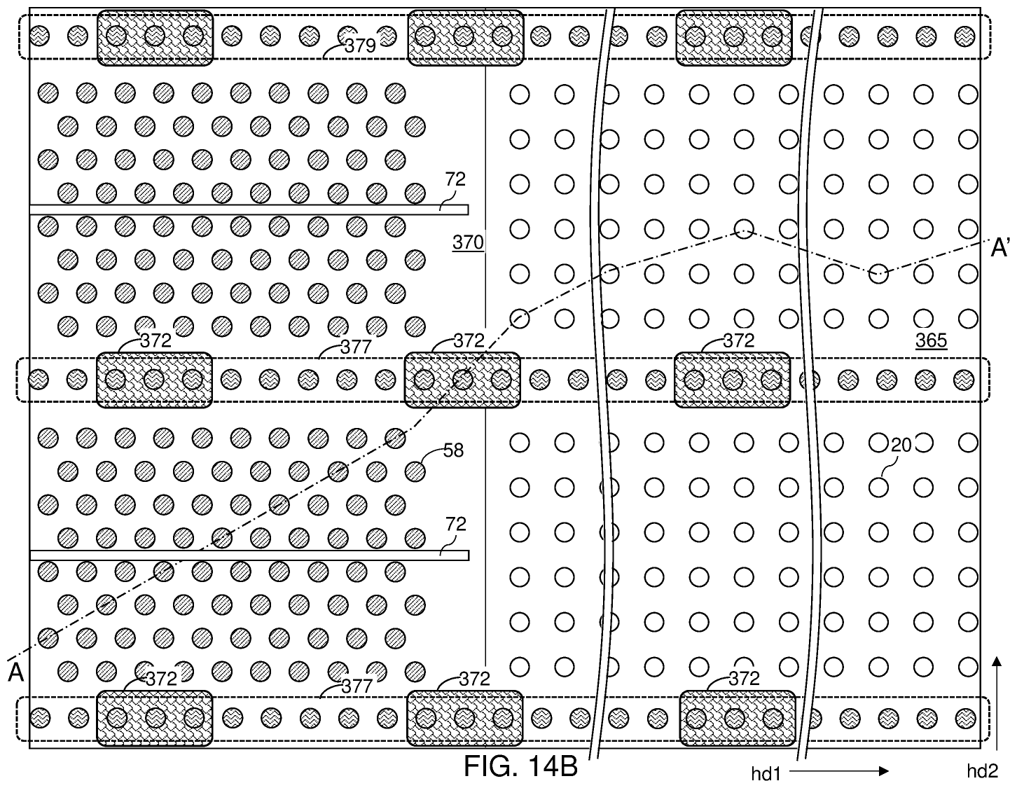

Referring to FIGS. 14A and 14B, the exemplary structure is illustrated after the processing steps described with reference to FIG. 13D. Memory opening fill structures 58 are formed in the memory openings 49. Each of the memory opening fill structure comprises a respective vertical semiconductor channel 60. Each of the memory opening fill structures 58 comprises a first tapered sidewall vertically extending through the first-tier structure, an optional second tapered sidewall vertically extending through the second-tier structure, an optional third tapered sidewall vertically extending through the third-tier structure, a first annular planar surface located within a first horizontal plane including a topmost surface of the first-tier structure and having an inner periphery that is adjoined to a bottom periphery of the second tapered sidewall and having an outer periphery that is adjoined to a top periphery of the first tapered sidewall, and an optional second annular planar surface located within a second horizontal plane including a topmost surface of the second-tier structure and having an inner periphery that is adjoined to a bottom periphery of the third tapered sidewall and having an outer periphery that is adjoined to a top periphery of the second tapered sidewall.

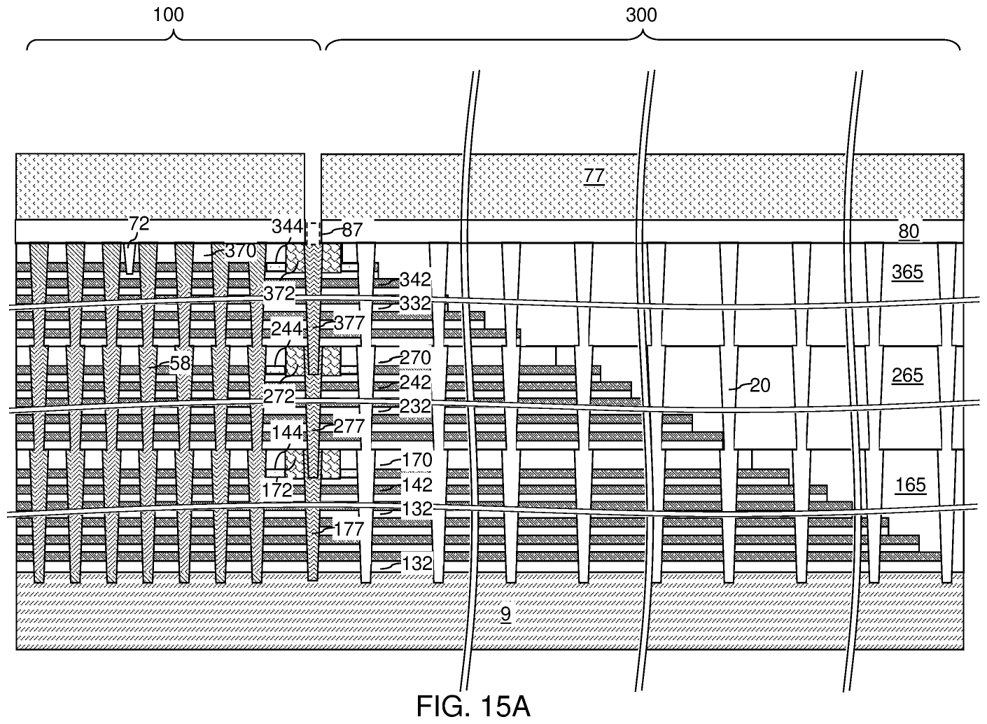

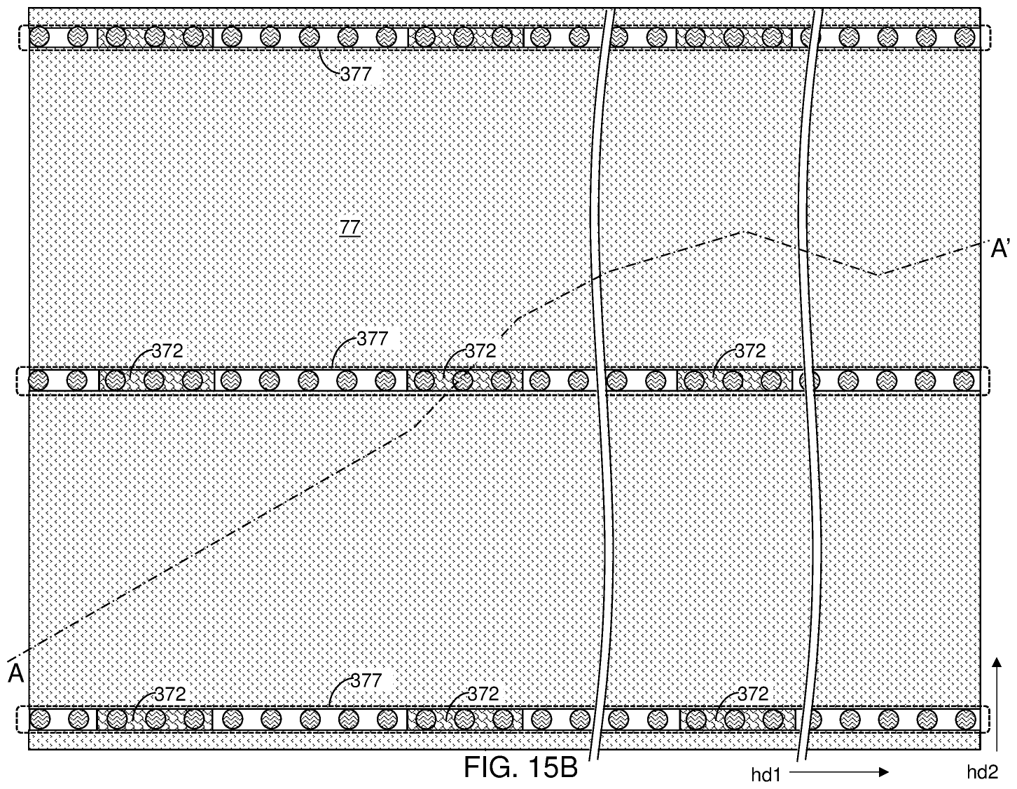

Referring to FIGS. 15A and 15B, a contact-level dielectric layer 80 can be deposited over the third insulating cap layer 370. The contact-level dielectric layer 80 comprises a dielectric material, such as silicon oxide, and may have a thickness in a range from 100 nm to 800 nm, although lesser and greater thicknesses may also be employed.

A photoresist layer 77 can be applied over the contact-level dielectric layer 80, and can be lithographically patterned to form strip-shaped openings that overlie a respective row of sacrificial isolation opening fill material portions (177, 277, 377). An anisotropic etch process can be performed to form slit-shaped openings through the contact-level dielectric layer 80 over the areas of the sacrificial isolation opening fill material portions (177, 277, 377). The slit-shaped openings are herein referred to as contact-level openings 87.

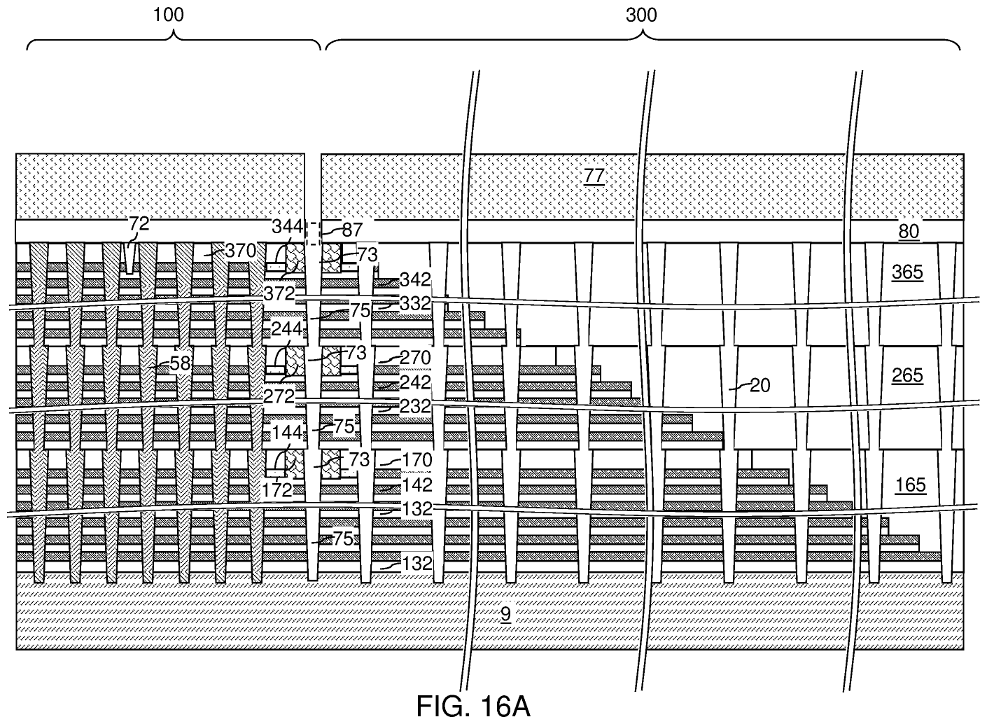

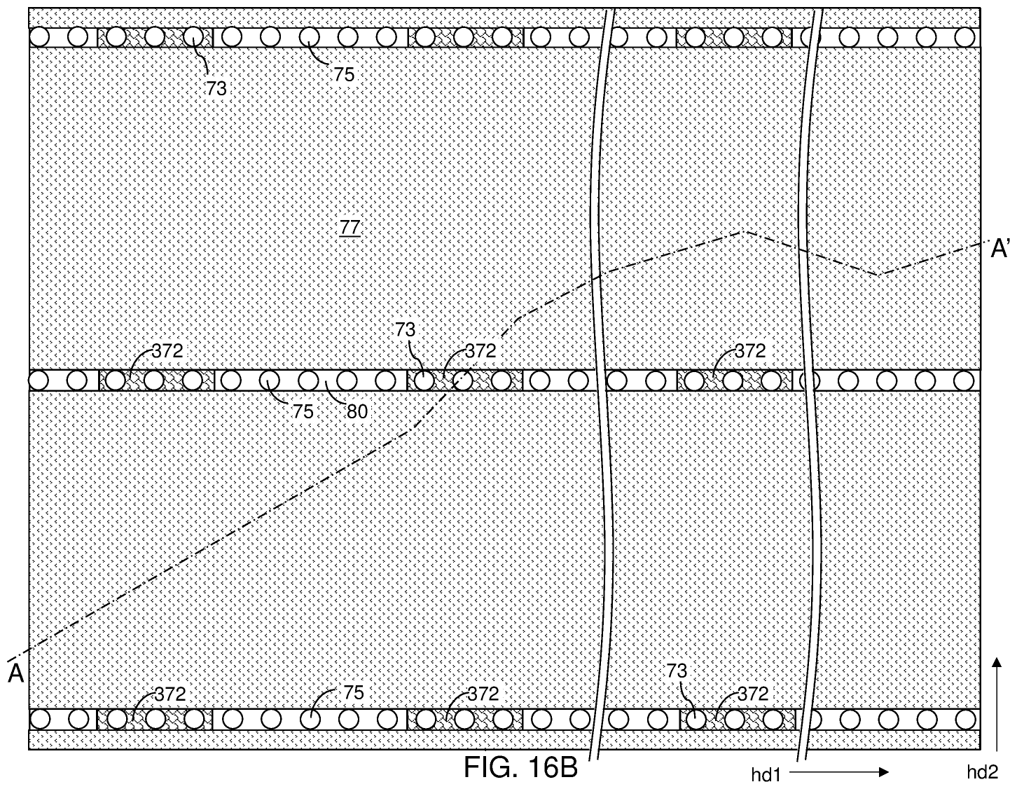

Referring to FIGS. 16A and 16B, an ashing or a selective etching process can be performed to remove the various sacrificial isolation opening fill material portions (177, 277, 377). Vertically-extending perforations 73 and inter-tier isolation openings 75, which are also referred to as isolation openings 75, can be formed in the volumes from which the materials of the sacrificial isolation opening fill material portions (377, 277, 177) are removed. The vertically-extending perforations 73 extend through the bridge structures (172, 272, 372) while the inter-tier isolation openings 75 are located between laterally adjacent and vertically adjacent bridge structures (172, 272, 372) However, the bridge structures (172, 272, 372) are not removed and remain located laterally between, above and below the inter-tier isolation openings 75 because the bridge structures (172, 272, 372) comprise a semiconductor material which is not removed by ashing or selective etching of the sacrificial isolation opening fill material portions (377, 277, 177)

Each of the inter-tier isolation openings 75 comprises a first tapered sidewall vertically extending through the first-tier structure, an optional second tapered sidewall vertically extending through the second-tier structure, and an optional third tapered sidewall vertically extending through the third-tier structure.

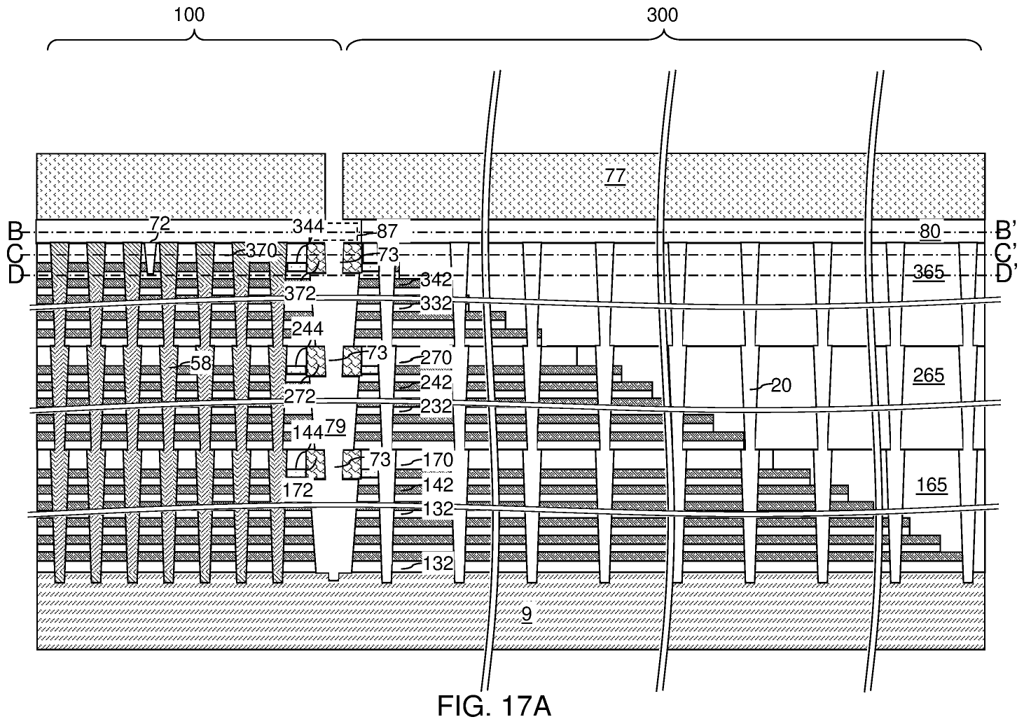

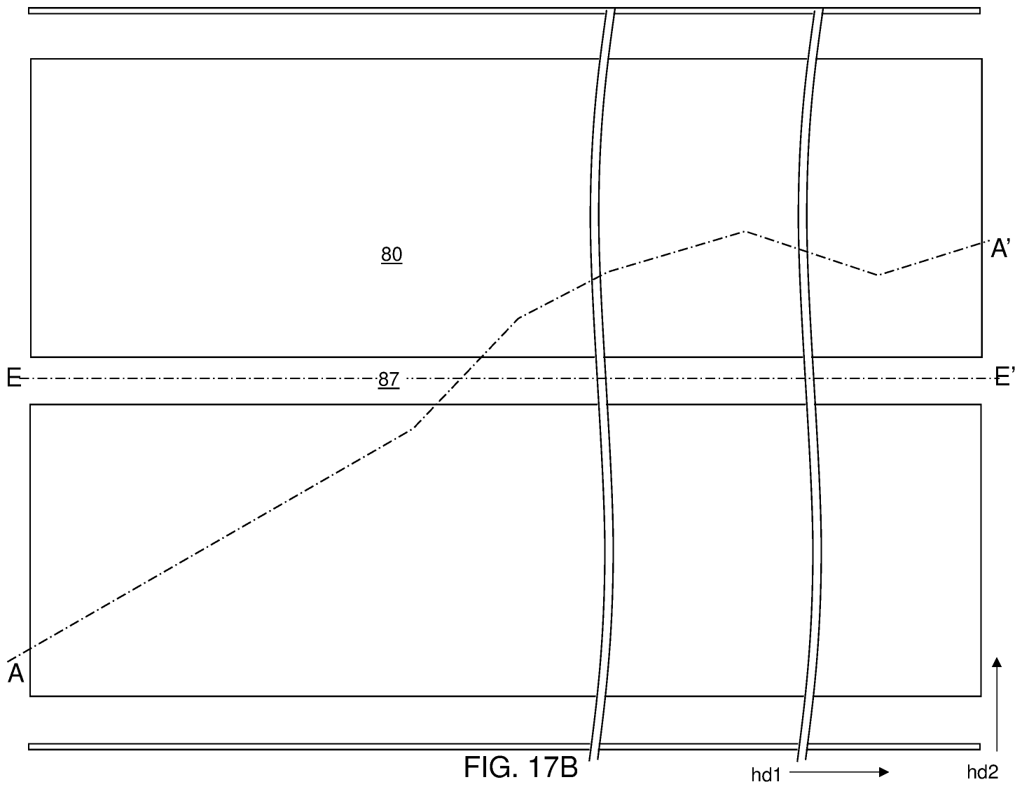

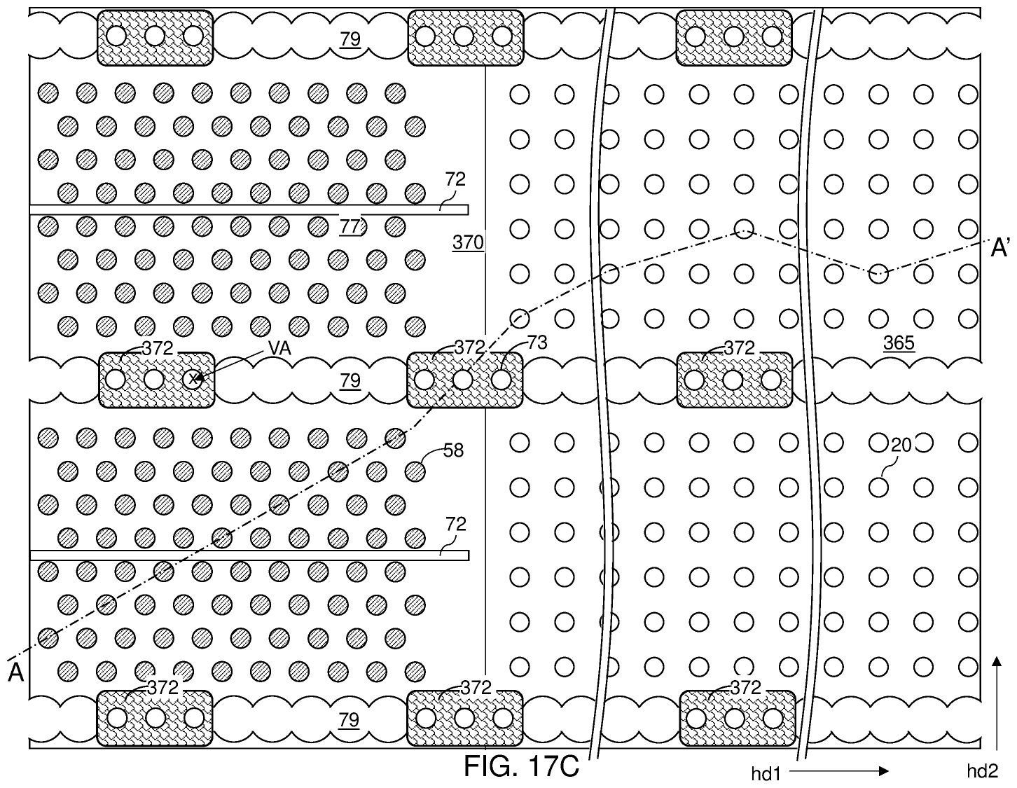

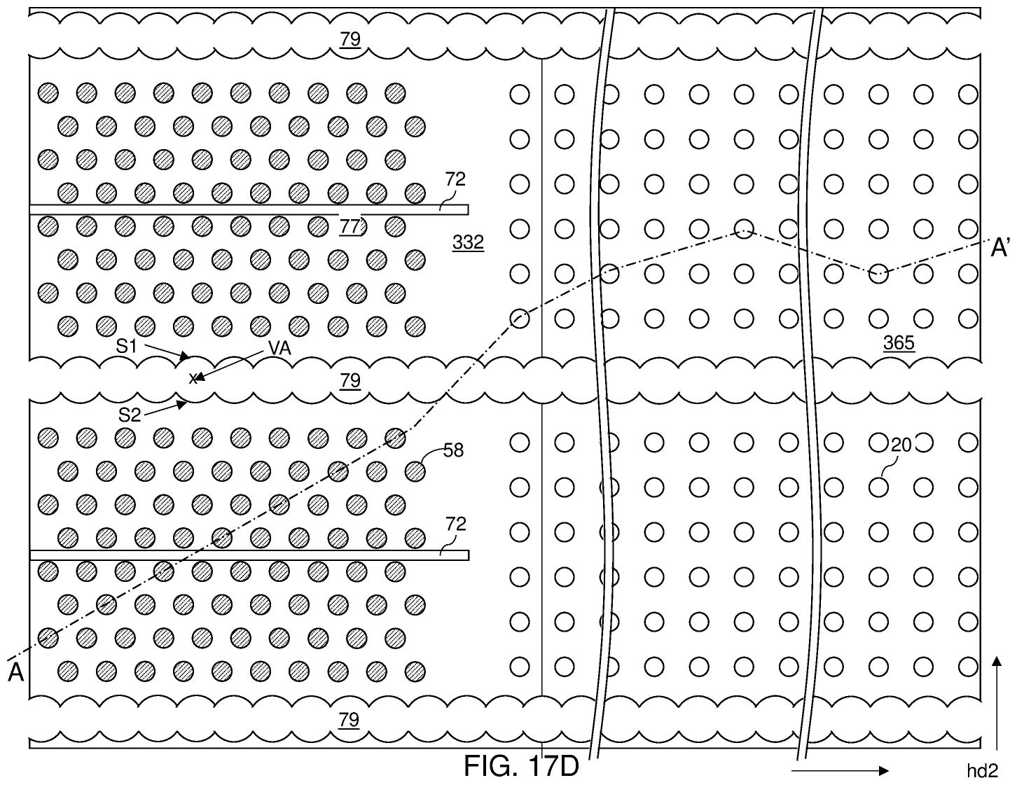

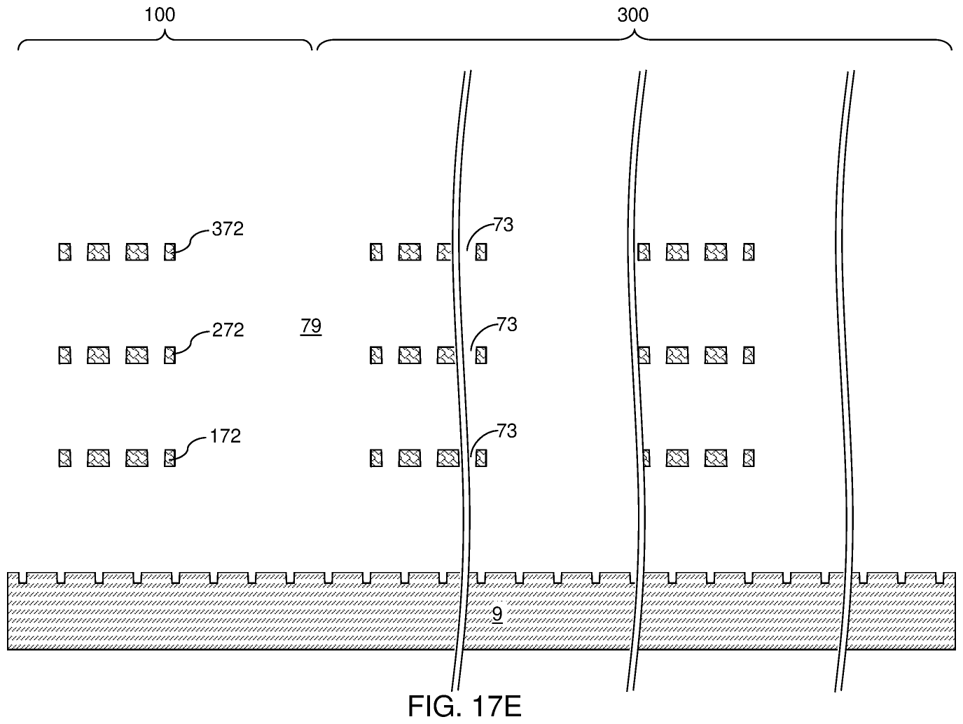

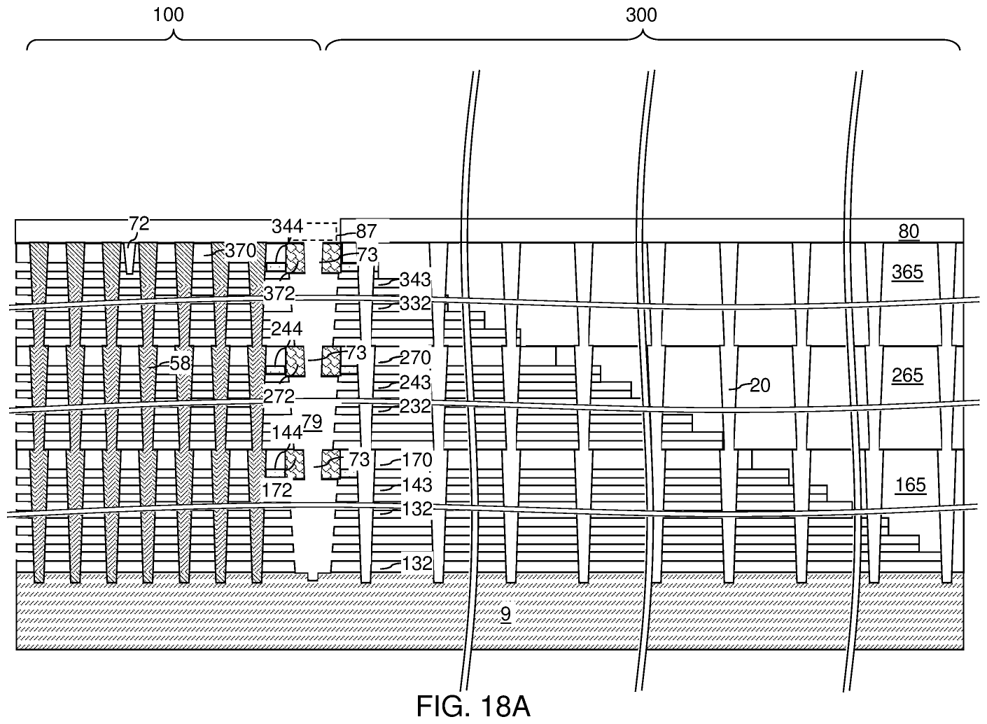

Referring to FIGS. 17A-17E, at least one selective isotropic etch process can be performed to etch the materials of the insulating layers (132, 232, 332), the sacrificial material layers (142, 242, 342), and the insulating cap layers (170, 270, 370) selective to the semiconductor materials of the bridge structures (172, 272, 372) and the carrier substrate 9. For example, if the insulating layers (132, 232, 332) and the insulating cap layers (170, 270, 370) comprise silicon oxide and if the sacrificial material layers (142, 242, 342) comprise silicon nitride, a wet etch process employing a buffered oxide etch (BOE) solution (which comprises a mixture of hydrofluoric acid about 5-7% in volume percentage, ammonium hydroxide about 25-40% in volume percentage, and deionized water) can be employed to isotropically etch the materials of the insulating layers (132, 232, 332), the sacrificial material layers (142, 242, 342), and the insulating cap layers (170, 270, 370) at about the same etch rate. The duration of the at least one selective isotropic etch process can be selected such that each row of inter-tier isolation openings 75 merge to form a respective lateral isolation cavity 79.

Generally, the inter-tier isolation openings 75 can be isotropically expanded by performing a first isotropic etch process which isotropically etches the first alternating stack (132, 142), the second alternating stack (232, 242), and the third alternating stack (332, 342) selective to the first-tier bridge structures 172, the second-tier bridge structures 272, and the third-tier bridge structures 372. A continuous lateral isolation cavity 79 is formed in each volume formed by merging of a respective row of inter-tier isolation openings 75.

Generally, the combination of the first alternating stack (132, 142), the optional second alternating stack (232, 242), and the optional third alternating stack (332, 342) as provided after the processing steps of FIGS. 16A and 16B can be divided into multiple laterally-spaced layer stacks (e.g., memory blocks) that are laterally spaced apart from each other by lateral isolation trenches. The lateral isolation trenches (172, 272, 372, 79) include the volumes of the bridge structures (172, 272, 372) and the lateral isolation cavities 79. In other words, each lateral isolation trench (172, 272, 372, 79) comprises a volume of a lateral isolation cavities 79 and further comprises volumes of a subset of the bridge structures (172, 272, 372) located in the respective lateral isolation cavity 79. Accordingly, each lateral isolation trench (172, 272, 372, 79) is filled with a respective row of first-tier bridge structures 172, a respective row of second-tier bridge structures 272, and a respective row of third-tier bridge structures 372.

The lateral isolation cavity 79 is located between a neighboring pair of first alternating stacks (132, 142), between a neighboring pair of second alternating stacks (232, 242), and between a neighboring pair of third alternating stacks (332, 342). Each lateral isolation trench (172, 272, 372, 79) comprises a pair of lengthwise sidewalls that laterally extend generally along a first horizontal direction hd1. Each lengthwise sidewall of the lateral isolation trench (172, 272, 372, 79) comprises first vertically-straight and laterally-concave surface segments of the first-tier structure that are adjoined to each other at first vertically-extending edges, optional second vertically-straight and laterally-concave surface segments of the second-tier structure that are adjoined to each other at second vertically-extending edges, and optional third vertically-straight and laterally-concave surface segments of the third-tier structure that are adjoined to each other at third vertically-extending edges. As used herein, a “vertically-straight” surface segment refers to a surface segment that has a straight vertical cross-sectional profile. As used herein, a “laterally-concave” surface segment refers to a surface segment that has a concave horizontal cross-sectional profile.

In one embodiment, a first subset of the first vertically-straight and laterally-concave surface segments of the first-tier structure vertically extends from a topmost surface of the first-tier structure to the first horizontal plane including the bottom surfaces of the first-tier bridge structures 172. A second subset of the first vertically-straight and laterally-concave surface segments of the first-tier structure is located entirely below the horizontal plane including the bottom surfaces of the first-tier bridge structures 172. In one embodiment, a first subset of the second vertically-straight and laterally-concave surface segments of the second-tier structure vertically extends from a topmost surface of the second-tier structure to the second horizontal plane including the bottom surfaces of the second-tier bridge structures 272. A second subset of the second vertically-straight and laterally-concave surface segments of the second-tier structure is located entirely below the horizontal plane including the bottom surfaces of the second-tier bridge structures 272. In one embodiment, a first subset of the third vertically-straight and laterally-concave surface segments of the second-tier structure vertically extends from a topmost surface of the third-tier structure to the third horizontal plane including the he bottom surfaces of the third-tier bridge structures 372. A second subset of the third vertically-straight and laterally-concave surface segments of the third-tier structure is located entirely below the horizontal plane including the bottom surfaces of the third-tier bridge structures 372.

In one embodiment, points of center of curvature for a facing pair of first vertically-straight and laterally-concave surface segments of the first-tier structure are located on a vertical line that passes through a geometrical center of one of the vertically-extending perforations 73 in the first-tier bridge structures 172. In one embodiment, points of center of curvature for a facing pair of second vertically-straight and laterally-concave surface segments of the second-tier structure are located on a vertical line that passes through a geometrical center of one of the vertically-extending perforations 73 in the second-tier bridge structures 272. In one embodiment, points of center of curvature for a facing pair of third vertically-straight and laterally-concave surface segments of the third-tier structure are located on a vertical line that passes through a geometrical center of one of the vertically-extending perforations 73 in the third-tier bridge structures 372.

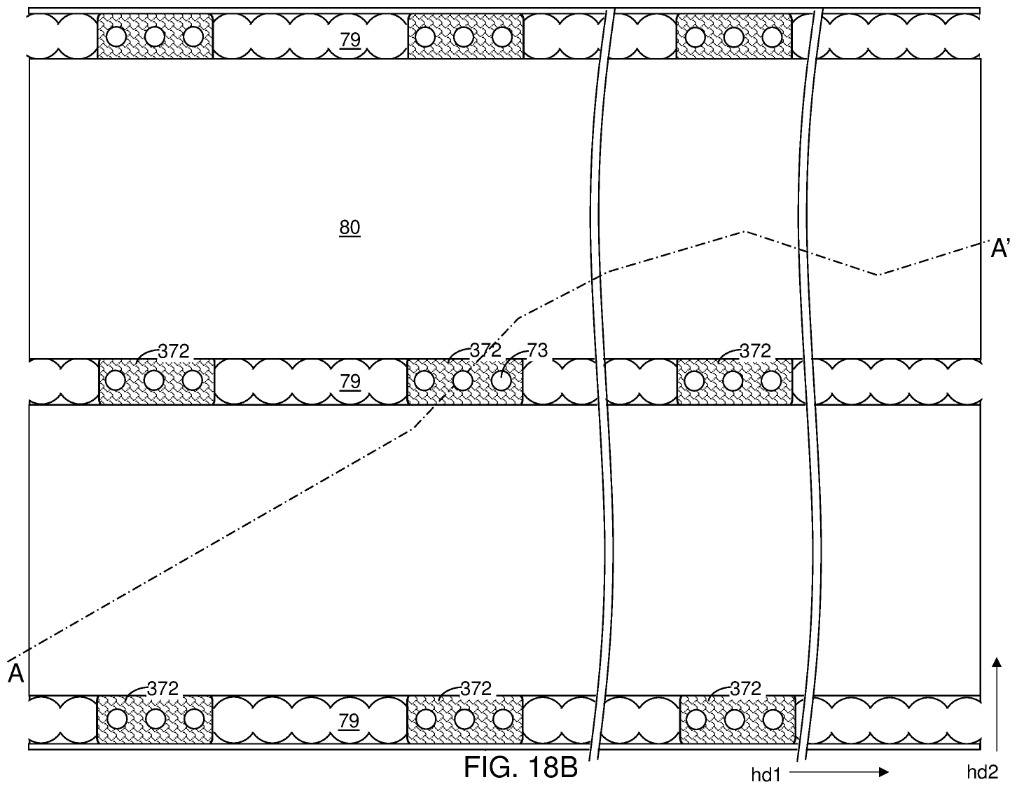

Referring to FIGS. 18A and 18B, an isotropic etch process can be performed to remove the sacrificial material layers (142, 242, 342) selective to the insulating layers (132, 232, 332), the insulating cap layers (170, 270, 370), the contact-level dielectric layer 80, the bridge structures (372, 272, 172), the lateral fin spacers (144, 244, 344), the memory opening fill structures 58, the support pillar structures 20, and the carrier substrate 9. In an illustrative example, the insulating layers (132, 232, 332) and the lateral fin spacers (144, 244, 344) may comprise silicon oxide, the sacrificial material layers (142, 242, 342) may comprise silicon nitride and the carrier substrate 9 and the bridge structures (372, 272, 172) may comprise silicon. In this case, the isotropic etch process that removes the sacrificial material layers (142, 242, 342) may comprise a wet etch process employing hot phosphoric acid which is provided to the alternating stacks through the lateral isolation cavities 79. Laterally-extending cavities (143, 243, 343) can be formed in volumes from which the sacrificial material layers (142, 242, 342) are removed. The laterally-extending cavities (143, 243, 343) may comprise first laterally-extending cavities 143 that are formed in volumes from which the first sacrificial material layers 142 are removed, second laterally-extending cavities 243 that are formed in volumes from which the second sacrificial material layers 242 are removed, and third laterally-extending cavities 343 that are formed in volumes from which the third sacrificial material layers 342 are removed. Sidewall surface segments of the memory opening fill structures 58 can be physically exposed to the laterally-extending cavities (143, 243, 343).

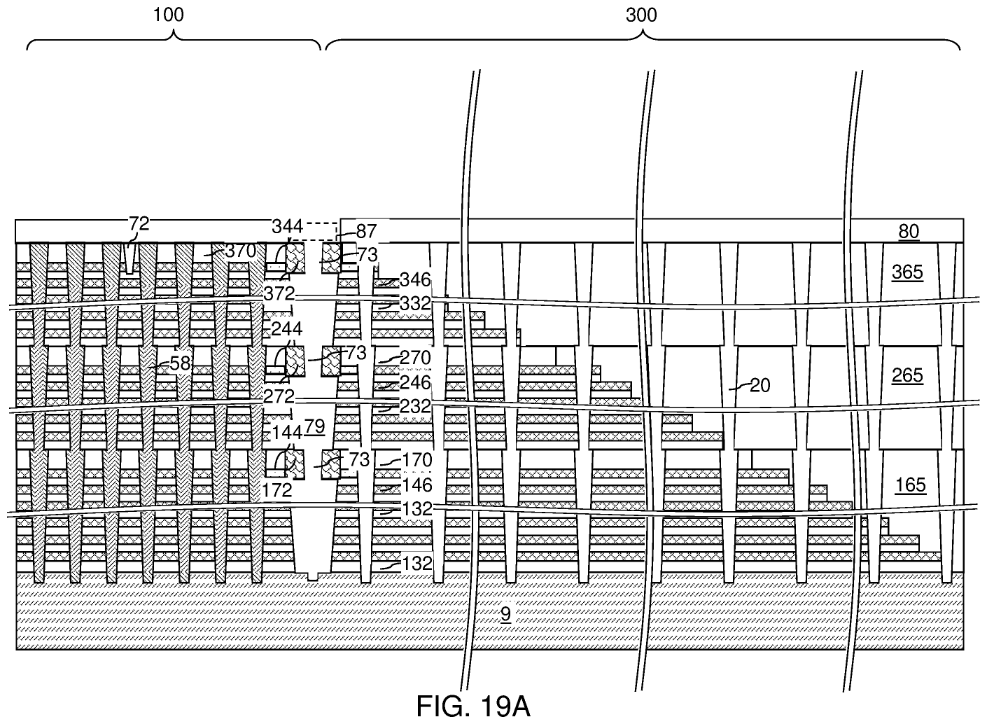

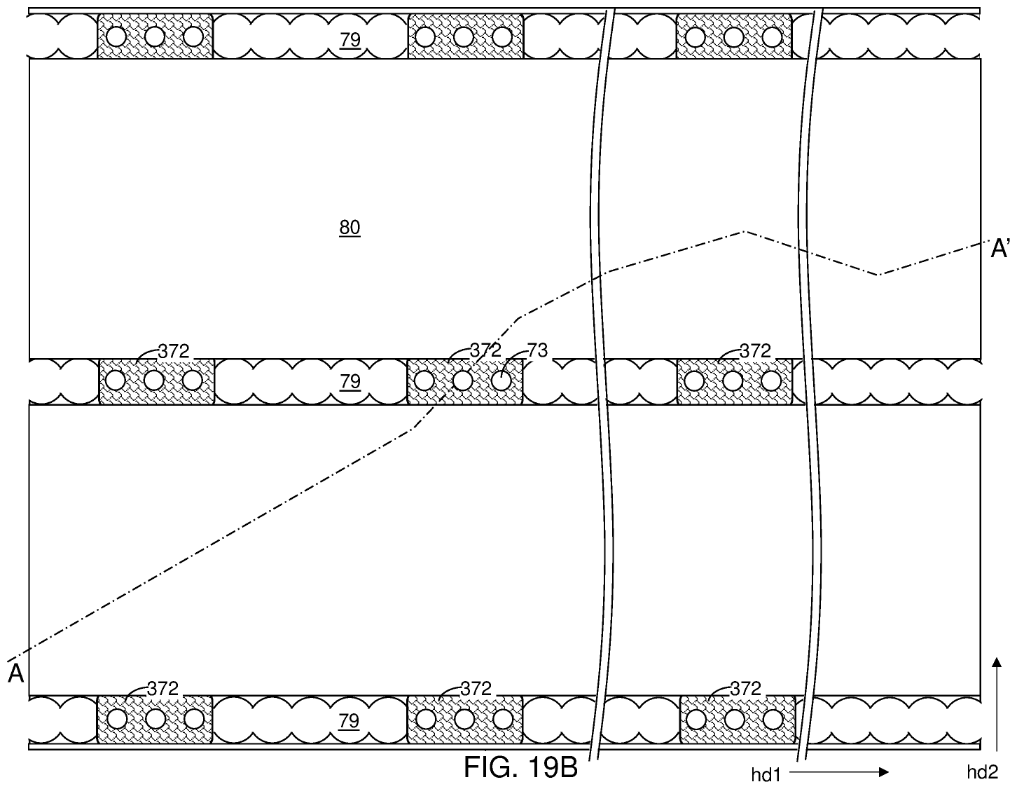

Referring to FIGS. 19A and 19B, an outer blocking dielectric layer (not shown), such as an aluminum oxide layer, can be optionally formed in the laterally-extending cavities (143, 243, 343) by a conformal deposition process. At least one conductive material, such as at least one metallic material, can be conformally deposited in the laterally-extending cavities (143, 243, 343). The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation cavities 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities (143, 243, 343) constitutes an electrically conductive layer (146, 246, 346). The electrically conductive layers (146, 246, 346) comprise first electrically conductive layers 146 that are interlaced with the first insulating layers 132, second electrically conductive layers 246 that are interlaced with the second insulating layers 232, and third electrically conductive layers 346 that are interlaced with the third insulating layers 332. An alternating stack of insulating layers (132, 232, 332) and electrically conductive layers (146, 246, 346) can be formed between each neighboring pair of lateral isolation trenches (172, 272, 372, 79) over the carrier substrate 9. A plurality of alternating stacks of insulating layers (132, 232, 332) and electrically conductive layers (146, 246, 346) can be laterally spaced apart from each other by the lateral isolation trenches (172, 272, 372, 79). Generally, the electrically conductive layers (146, 246, 346) can be formed in the laterally-extending cavities (143, 243, 343) by performing an isotropic conductive material deposition process that provides a reactant into the laterally-extending cavities (143, 243, 343) through the lateral isolation cavity 79 and deposits an electrically conductive material in the laterally-extending cavities (143, 243, 343) and by isotropically recessing the deposited electrically conductive material. The lateral fin spacers (144, 244, 344) prevent a short circuit between the electrically conductive layers (146, 246, 346) and the semiconductor bridge structures (172, 272, 372).

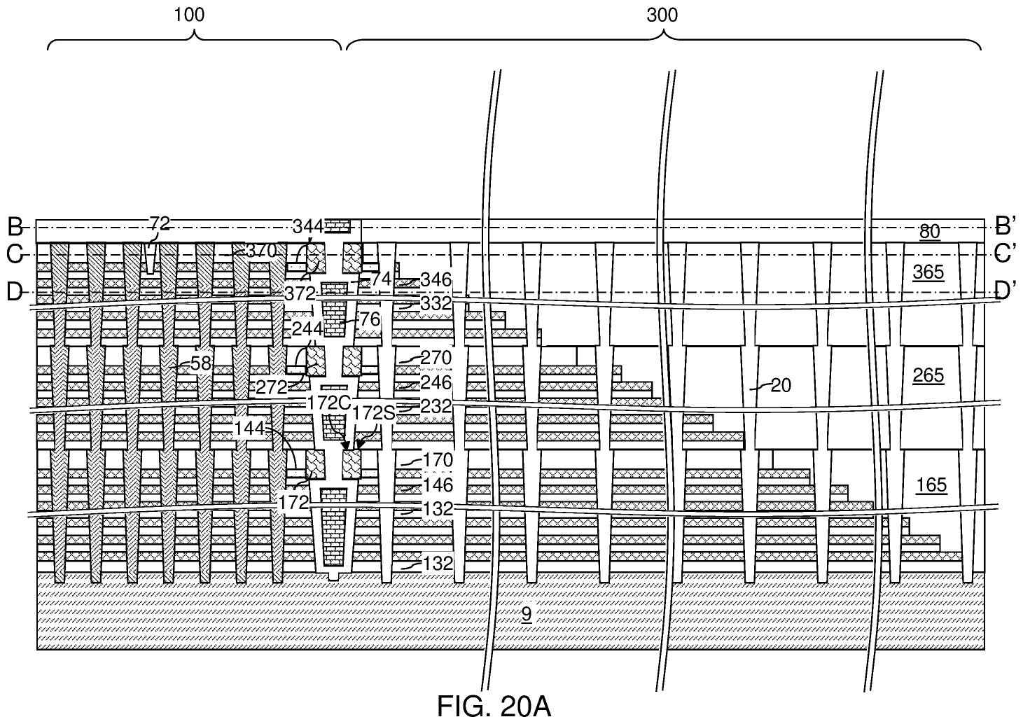

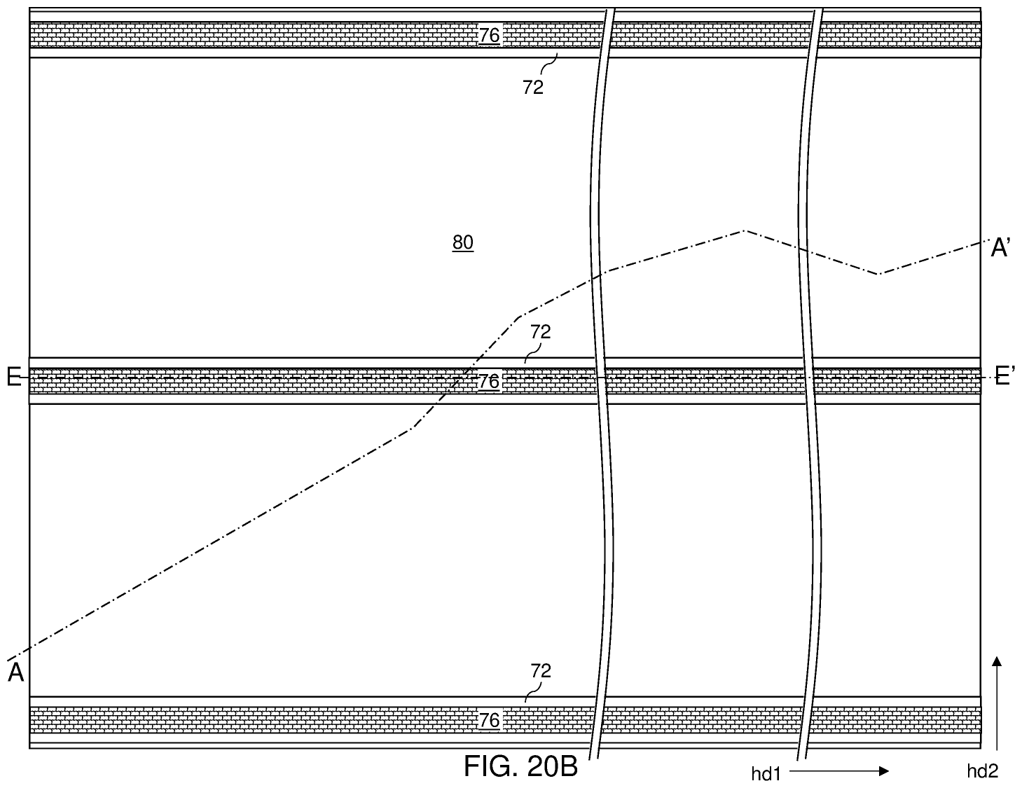

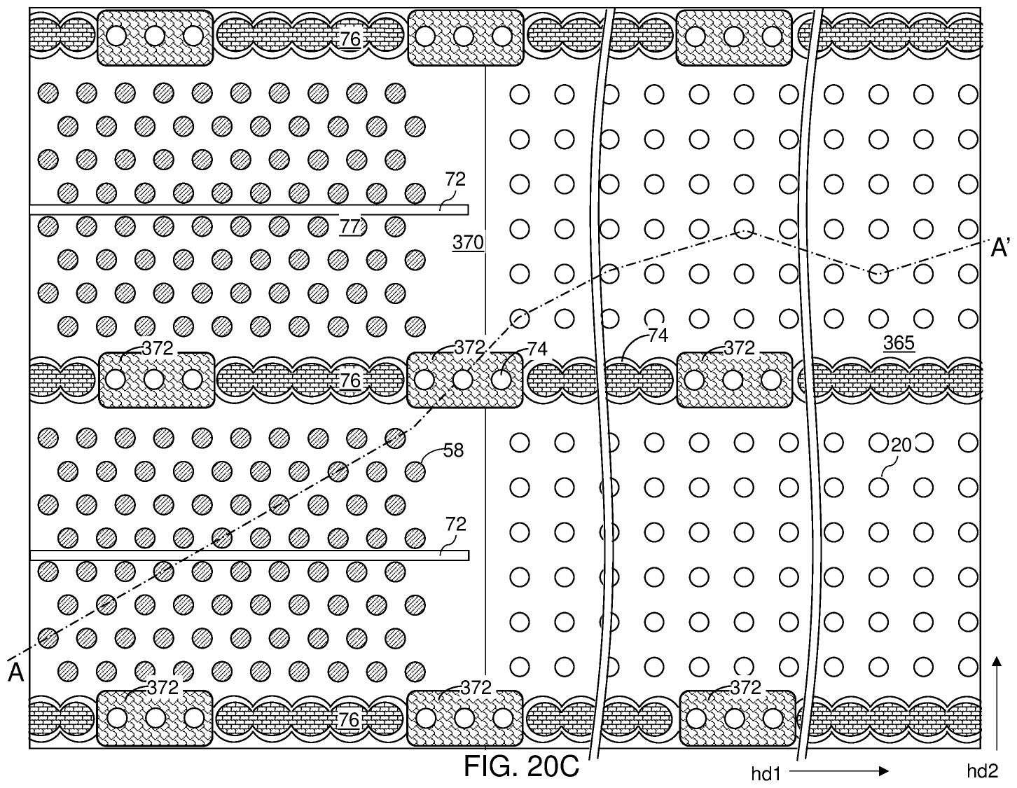

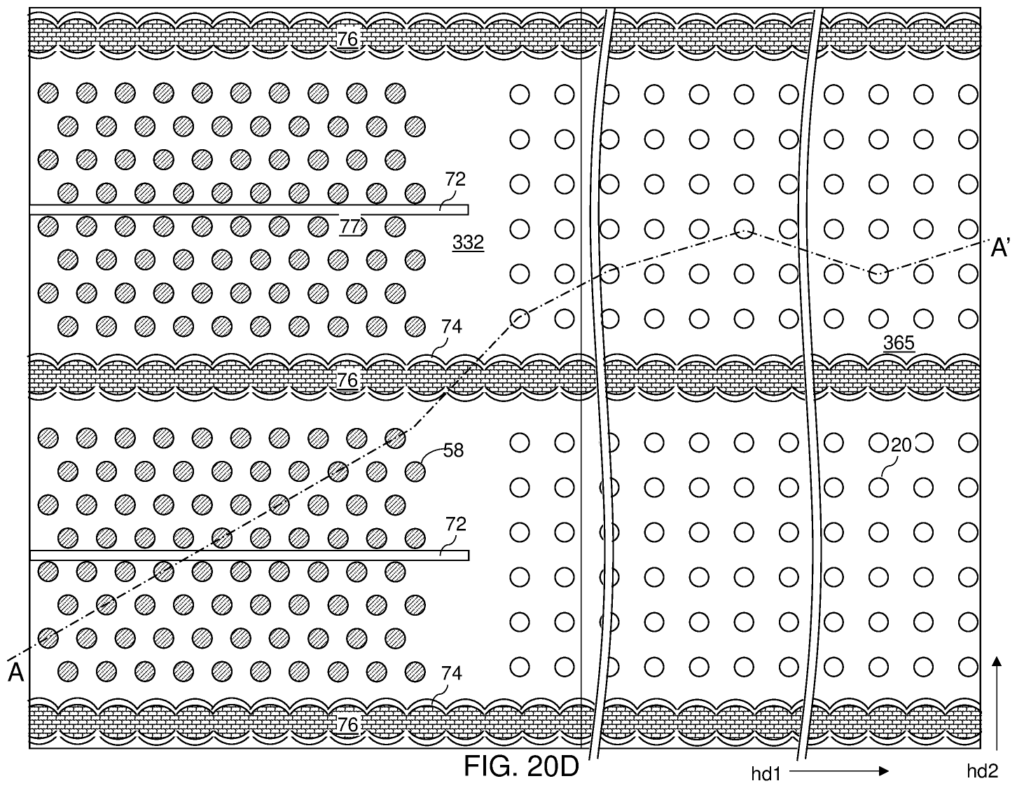

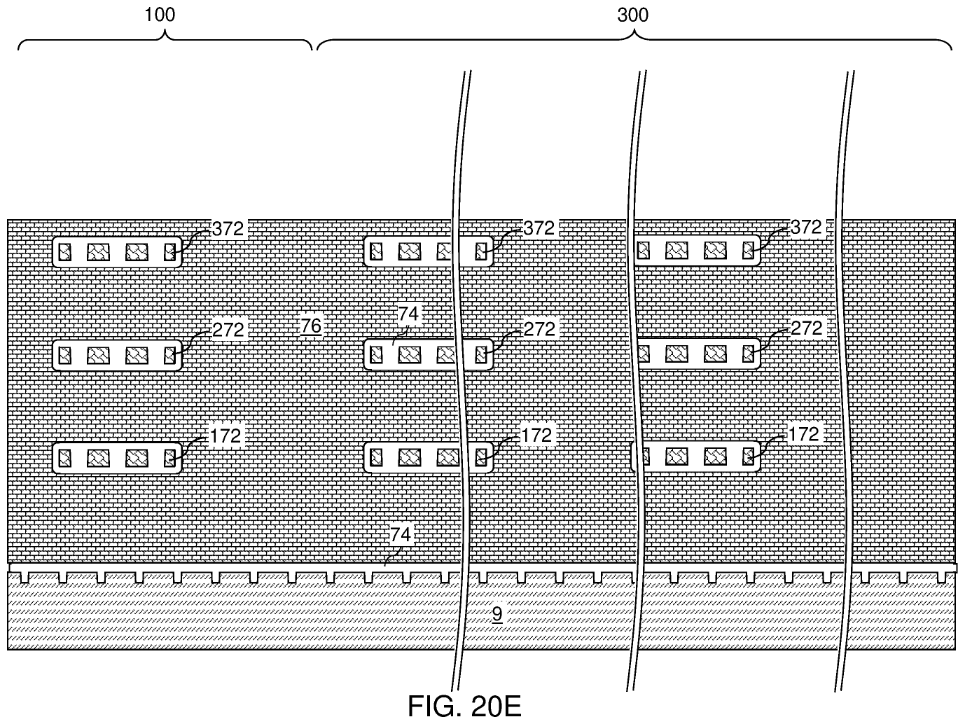

Referring to FIGS. 20A-20E, an insulating material layer can be conformally deposited on the physically exposed surfaces of the lateral isolation cavities 79 and the bridge structures (172, 272, 372). The insulating material layer comprises an insulating material, such as silicon oxide. In one embodiment, the thickness of the insulating material layer may be greater than the radius of each perforation 73 through the bridge structures (172, 272, 372). In one embodiment, the insulating material may have a thickness that is less than one half of a minimum spacing of each lateral isolation cavity 79 along the second horizontal direction hd2 and may only partially fill each lateral isolation cavity 79. In another embodiment, the insulating material may have a thickness that is greater than one half of a minimum spacing of each lateral isolation cavity 79 along the second horizontal direction hd2, and may completely fill each lateral isolation cavity 79.

If the insulating material does not completely fill the lateral isolation cavity 79, then an optional conductive fill material, such as a metallic fill material, may be deposited in the remaining volumes of the lateral isolation cavities 79. Excess portions of the conductive fill material and the insulating material layer can be removed from above the horizontal plane including the top surface of the contact-level dielectric layer 80 by performing a planarization process, which may employ a chemical mechanical polishing process or a recess etch process. Each remaining portion of the insulating material layer filling a portion of a respective one of the lateral isolation trenches constitutes an insulating spacer 74. Each remaining portion of the conductive fill material filling a portion of a respective one of the lateral isolation trenches constitutes a trench fill material portion 76. Alternatively, if the insulating material completely fills the lateral isolation cavity 79, then the insulating spacer 74 completely fills the lateral isolation cavity 79 and the perforations 73.

Generally, an insulating spacer 74 can be formed at least in peripheral regions of a respective lateral isolation cavity 79 by performing a conformal deposition process. In one embodiment, an optional trench fill material portion 76 can be formed within a volume of the lateral isolation cavity 79 that is not filled with the insulating spacer 74. In one embodiment, each insulating spacer 74 continuously extends under bottom surfaces of a row of first-tier bridge structures 172, under bottom surfaces of a row of second-tier bridge structures 272, and under bottom surfaces of a row of third-tier bridge structures 372. In one embodiment, the insulating spacer 74 continuously extends into each vertically-extending perforation 73 in the row of first-tier bridge structures 172, into each vertically-extending perforation in the row of second-tier bridge structures 272, and into each vertically-extending perforation in the row of third-tier bridge structures 372.

Generally, a lateral isolation trench (172, 272, 372, 79) can be provided between each neighboring pair of first alternating stacks (132, 146), between each neighboring pair of second alternating stacks (232, 246), and between each neighboring pair of third alternating stacks (332, 342). Each lateral isolation trench (172, 272, 372, 79) comprises a pair of lengthwise sidewalls that laterally extend generally along a first horizontal direction hd1. In one embodiment, each lengthwise sidewall of a lateral isolation trench (172, 272, 372, 79) comprises first vertically-straight and laterally-concave surface segments of the first-tier structure that are adjoined to each other at first vertically-extending edges, second vertically-straight and laterally-concave surface segments of the second-tier structure that are adjoined to each other at second vertically-extending edges, and third vertically-straight and laterally-concave surface segments of the third-tier structure that are adjoined to each other at third vertically-extending edges.

A lateral isolation trench fill structure (172, 272, 372, 74, 76) can be located in each lateral isolation trench (172, 272, 372, 79). In one embodiment, the lateral isolation trench fill structure (172, 272, 372, 74, 76) may comprise first-tier bridge structures 172 each having a respective set of at least one vertically-extending perforation 73 therethrough and having a respective top surface located within a first horizontal plane including a topmost surface of the first-tier structure (such as the horizontal plane including the top surface of the first insulating cap layer 170); second-tier bridge structures 272 each having a respective set of at least one vertically-extending perforation 73 therethrough and having a respective top surface located within a second horizontal plane including a topmost surface of the second-tier structure (such as the horizontal plane including the top surface of the second insulating cap layer 270); third-tier bridge structures 372 each having a respective set of at least one vertically-extending perforation 73 therethrough and having a respective top surface located within a third horizontal plane including a topmost surface of the third-tier structure (such as the horizontal plane including the top surface of the third insulating cap layer 370); an insulating spacer 74 continuously extending over sidewalls of the lateral isolation trench (172, 272, 372, 79) and filling the perforations 73; and an optional trench fill material portion 76 filling an optional volume laterally bounded by the insulating spacer 74.

In one embodiment, the first-tier bridge structures 172 comprises lengthwise sidewalls that laterally extend along a first horizontal direction hd1 and widthwise sidewalls that laterally extend along a second horizontal direction hd2 that is perpendicular to the first horizontal direction hd1; the second-tier bridge structures 272 comprises lengthwise sidewalls that laterally extend along the first horizontal direction hd1 and widthwise sidewalls that laterally extend along the second horizontal direction hd2; and the third-tier bridge structures 372 comprises lengthwise sidewalls that laterally extend along the first horizontal direction hd1 and widthwise sidewalls that laterally extend along the second horizontal direction hd2.

In one embodiment, the insulating spacer 74 contacts each widthwise sidewall of the first-tier bridge structures 172 within the lateral isolation trench, contacts each widthwise sidewall of the second-tier bridge structures 272 within the lateral isolation trench, and contacts each widthwise sidewall of the third-tier bridge structures 372 within the lateral isolation trench.

In one embodiment, the first-tier structure comprises a first insulating cap layer 170 that overlies the pair of first alternating stacks (132, 146) and having a topmost surface within the first horizontal plane. In one embodiment, the first insulating cap layer 170 has a thickness that is greater than a sum of a thickness of one of the first insulating layers 132 and a thickness of one of the first electrically conductive layers 146. In one embodiment, the second-tier structure comprises a second insulating cap layer 270 that overlies the pair of second alternating stacks (232, 246) and having a topmost surface within the second horizontal plane. In one embodiment, the second insulating cap layer 270 has a thickness that is greater than a sum of a thickness of one of the second insulating layers 232 and a thickness of one of the second electrically conductive layers 246. In one embodiment, the third-tier structure comprises a third insulating cap layer 370 that overlies the pair of third alternating stacks (332, 346) and having a topmost surface within the third horizontal plane. In one embodiment, the third insulating cap layer 370 has a thickness that is greater than a sum of a thickness of one of the third insulating layers 332 and a thickness of one of the third electrically conductive layers 346.

In one embodiment shown in FIG. 20A, the bridge structures (172, 272, 372) may have a greater width along the second horizontal direction hd2 than the width of an overlying portion of a lateral isolation trench (i.e., greater than the overlying portion of the lateral isolation cavity 79) at least partially filled by the insulating spacer 74. In one embodiment, each top surface of the first-tier bridge structures 172 comprises a center portion 172C that is contacted by an insulating spacer 74, and a pair of peripheral strip portions 172S that are contacted by bottom surface segments of the second-tier structure. In one embodiment, each top surface of the second-tier bridge structures 272 comprises a center portion that is contacted by the insulating spacer 74, and a pair of peripheral strip portions that are contacted by bottom surface segments of the third-tier structure. In one embodiment, each top surface of the third-tier bridge structures 372 comprises a center portion that is contacted by the insulating spacer 74, and a pair of peripheral strip portions that are contacted by bottom surface segments of the contact-level dielectric layer 80.

In one embodiment, points of center of curvature for a facing pair of first vertically-straight and laterally-concave surface segments of the first-tier structure are located on a vertical line that passes through a geometrical center of one of the vertically-extending perforations in the first-tier bridge structures 172. In one embodiment, points of center of curvature for a facing pair of second vertically-straight and laterally-concave surface segments of the second-tier structure are located on a vertical line that passes through a geometrical center of one of the vertically-extending perforations in the second-tier bridge structures 272. In one embodiment, points of center of curvature for a facing pair of third vertically-straight and laterally-concave surface segments of the third-tier structure are located on a vertical line that passes through a geometrical center of one of the vertically-extending perforations in the third-tier bridge structures 372.

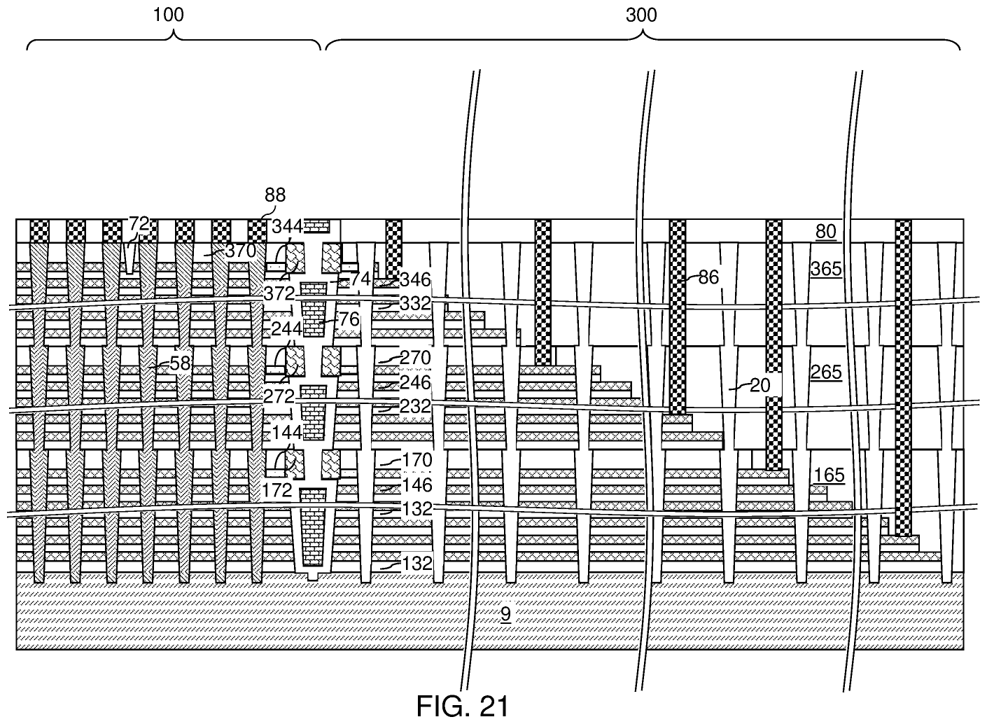

Referring to FIG. 21, via cavities can be formed through the contact-level dielectric layer 80 and through the stepped dielectric material portions (365, 265, 165). Drain contact via cavities can be formed over the drain regions 63 of the memory opening fill structures 58. Layer contact via structures can be formed over the electrically conductive layers (146, 246, 346) that underlie the stepped surfaces.

At least one conductive material, such as a combination of an electrically conductive barrier material and an electrically conductive fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88, which contact top surfaces of the drain regions 63. Remaining portions of the at least one conductive material that fill the layer contact via cavities constitute layer contact via structures 86, which contact top surfaces of the electrically conductive layers (146, 246, 346).

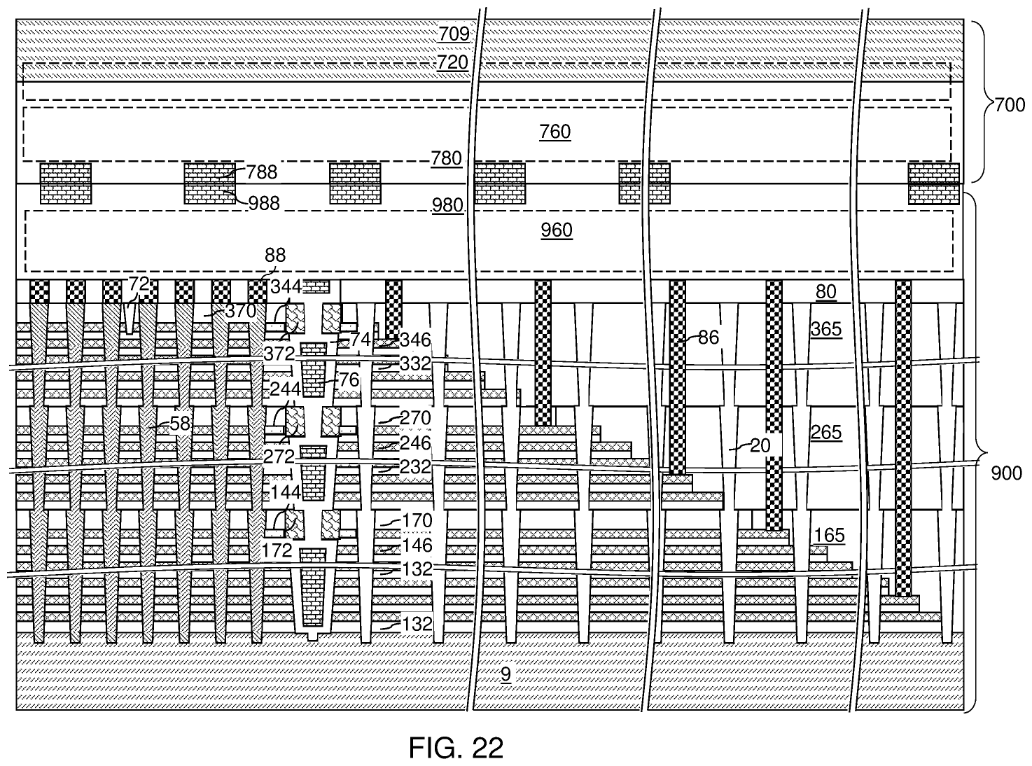

Referring to FIG. 22, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers (132, 232, 332) and electrically conductive layers (146, 246, 346) and the memory opening fill structures 58. A memory die 900 is formed by the above steps.

In one embodiment, the memory die 900 may comprise: a three-dimensional memory array comprising an alternating stack of insulating layers (132, 232, 332) and electrically conductive layers (146, 246, 346), a two-dimensional array of memory openings 49 vertically extending through the alternating stack, and a two-dimensional array of memory opening fill structures 58 located in the two-dimensional array of memory openings 49 and comprising a respective vertical stack of memory elements and a respective vertical semiconductor channel 60, a two-dimensional array of drain contact via structures 88 electrically connected to a respective one of the vertical semiconductor channels 60 via respective drain regions 63; and a two-dimensional array of layer contact via structures 86 electrically connected to a respective one of the electrically conductive layers (146, 246, 346), a subset of which functions as word lines for the three-dimensional memory array.

A logic die 700 can be provided. For example, a peripheral circuit 720 can be formed on a logic-side substrate 709, which can be a semiconductor substrate. The peripheral circuit 720 can be configured to control operation of the memory array within the memory die 900. Logic-side metal interconnect structures 780 embedded within logic-side dielectric material layers 760 can be formed over the logic-side substrate 709 (which may comprise a semiconductor substrate) to form a logic die 700. The logic die 700 also comprises logic-side bonding pads 788 embedded within logic-side dielectric material layers 760.

A bonded assembly can be formed by bonding the logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

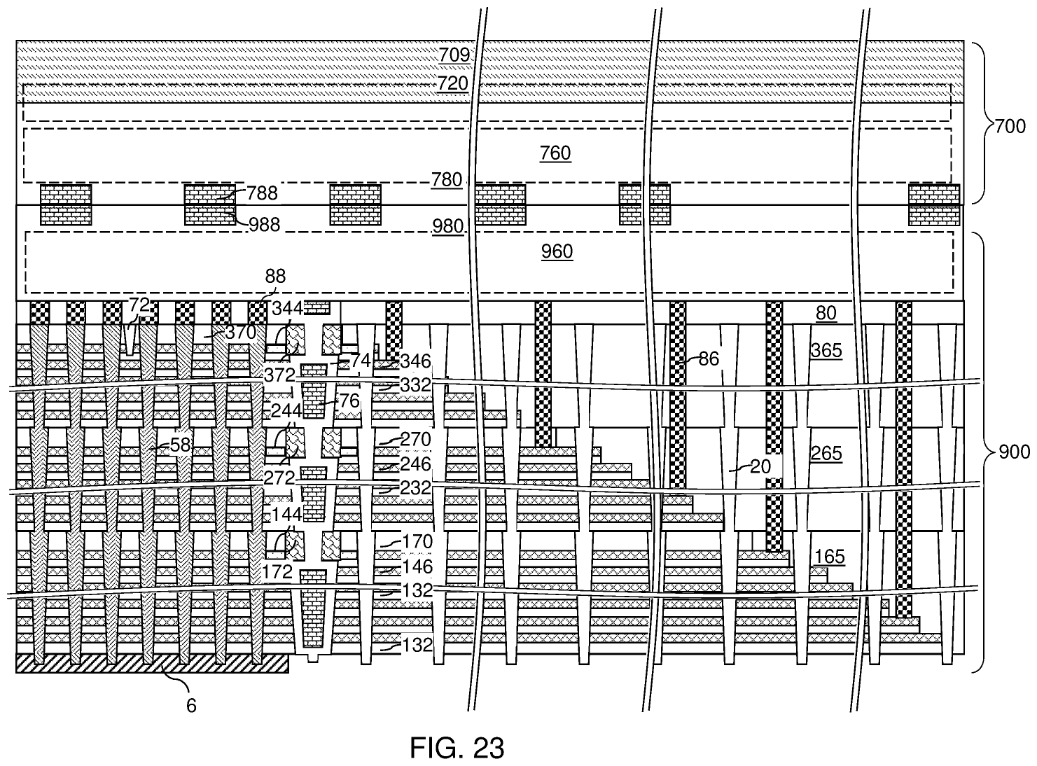

Referring to FIG. 23, the carrier substrate 9 can optionally be removed, for example, by grinding, polishing, cleaving, an isotropic etch process, and/or an anisotropic etch process. End portions of the memory film 50 can be removed selective to the vertical semiconductor channel 60 from each memory opening fill structure 58, for example, by performing an etch process that etches the materials of the memory film 50 selective to the material of the vertical semiconductor channel 60. At least one heavily doped semiconductor layer and/or an electrically conductive material layer can be deposited on physically exposed surfaces of the vertical semiconductor channels 60, and can be subsequently patterned to form a source layer 6.

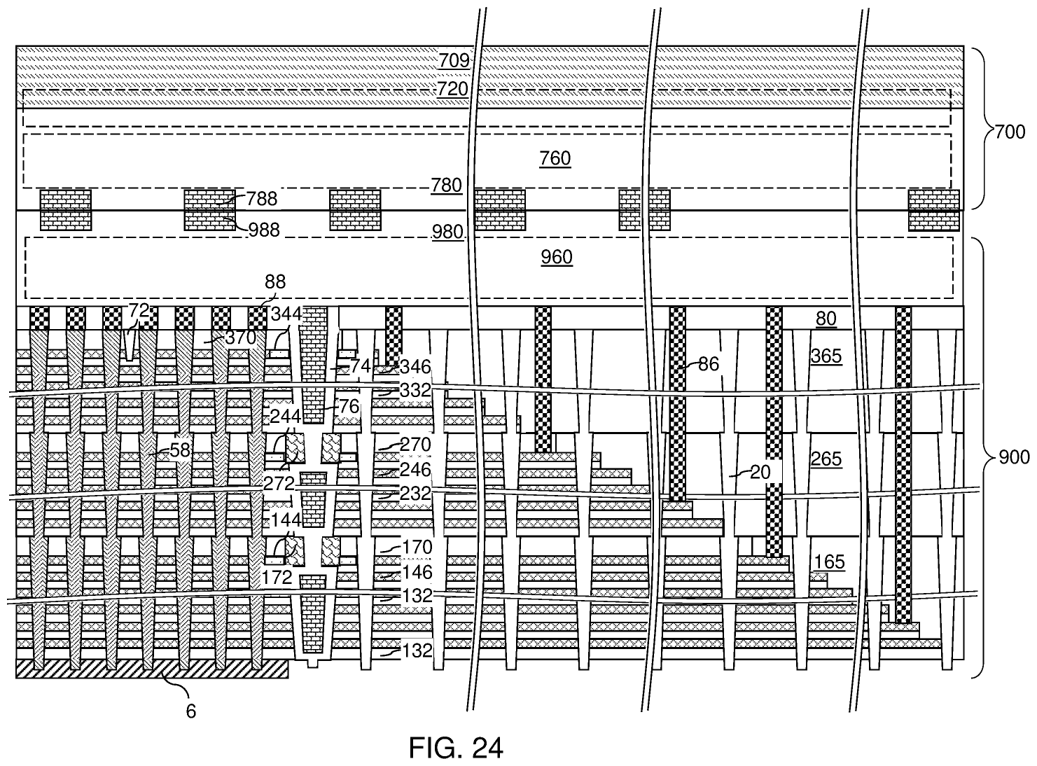

FIGS. 24-31 are vertical cross-sectional views of alternative configurations of the exemplary structures according to various embodiments of the present disclosure.

Referring to FIG. 24, a first alternative configuration of the exemplary structure is illustrated, which can be derived from the exemplary structure illustrated in FIG. 23 by omitting formation of the third-tier bridge structures 372.

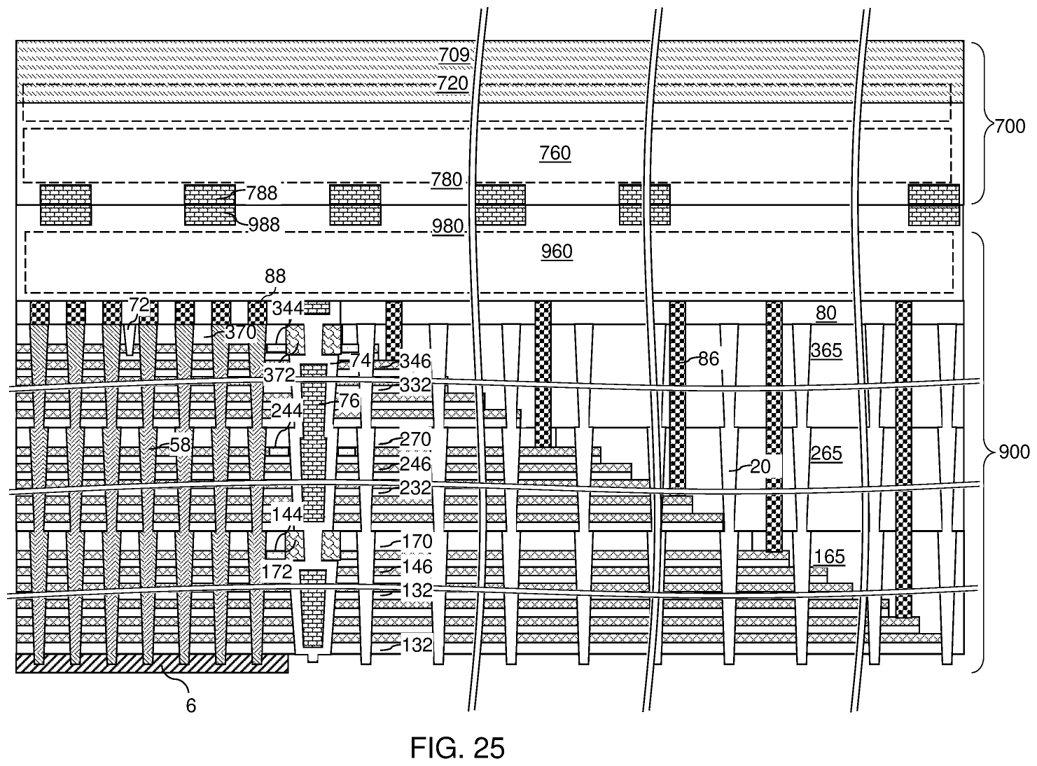

Referring to FIG. 25, a second alternative configuration of the exemplary structure is illustrated, which can be derived from the exemplary structure illustrated in FIG. 23 by omitting formation of the second-tier bridge structures 272.

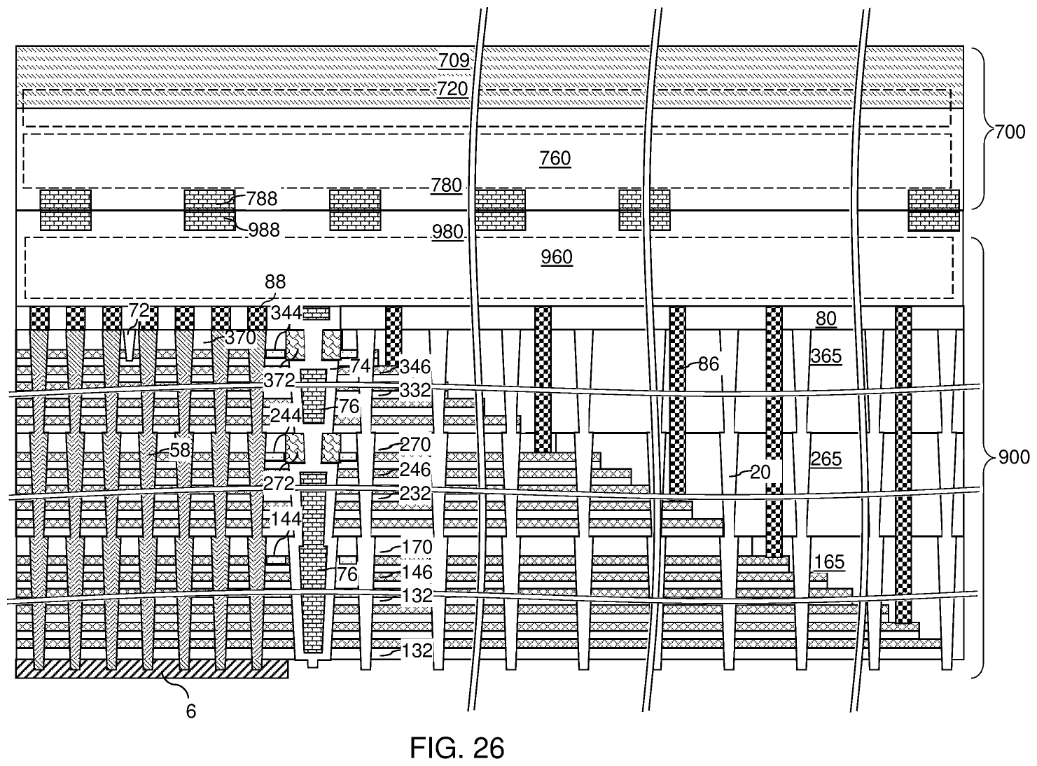

Referring to FIG. 26, a third alternative configuration of the exemplary structure is illustrated, which can be derived from the exemplary structure illustrated in FIG. 23 by omitting formation of the first-tier bridge structures 172.

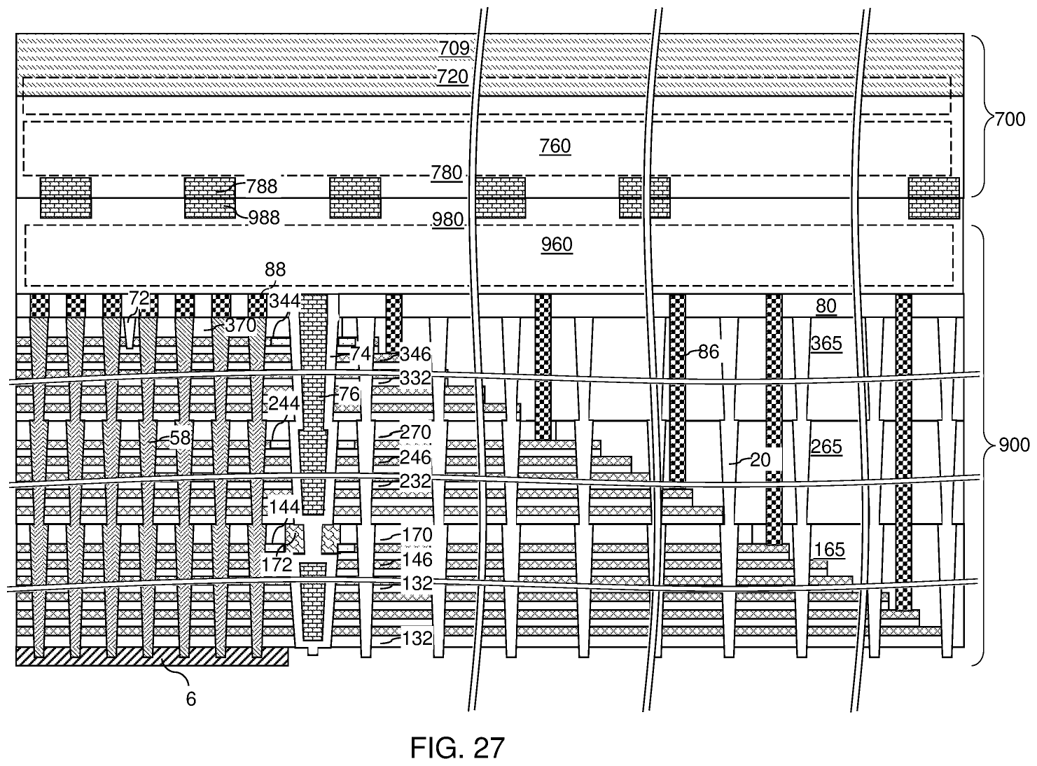

Referring to FIG. 27, a fourth alternative configuration of the exemplary structure is illustrated, which can be derived from the exemplary structure illustrated in FIG. 23 by omitting formation of the second-tier bridge structures 272 and the third-tier bridge structures 372.

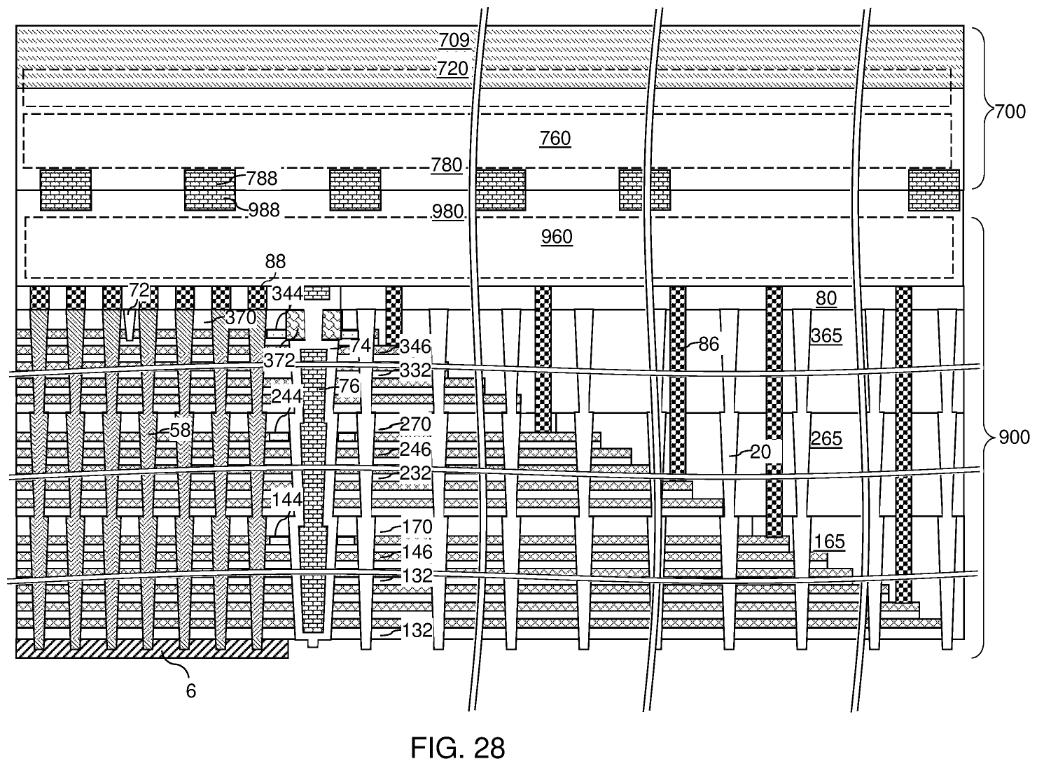

Referring to FIG. 28, a fifth alternative configuration of the exemplary structure is illustrated, which can be derived from the exemplary structure illustrated in FIG. 23 by omitting formation of the first-tier bridge structures 172 and the second-tier bridge structures 272.

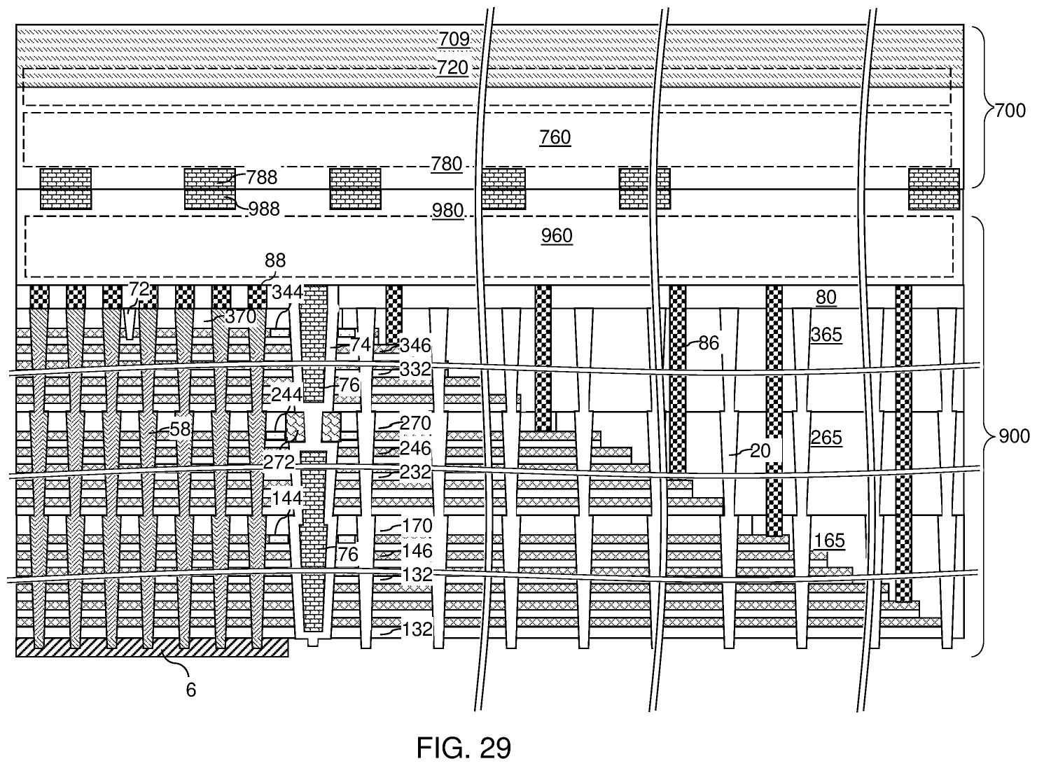

Referring to FIG. 29, a sixth alternative configuration of the exemplary structure is illustrated, which can be derived from the exemplary structure illustrated in FIG. 23 by omitting formation of the first-tier bridge structures 172 and the third-tier bridge structures 372.

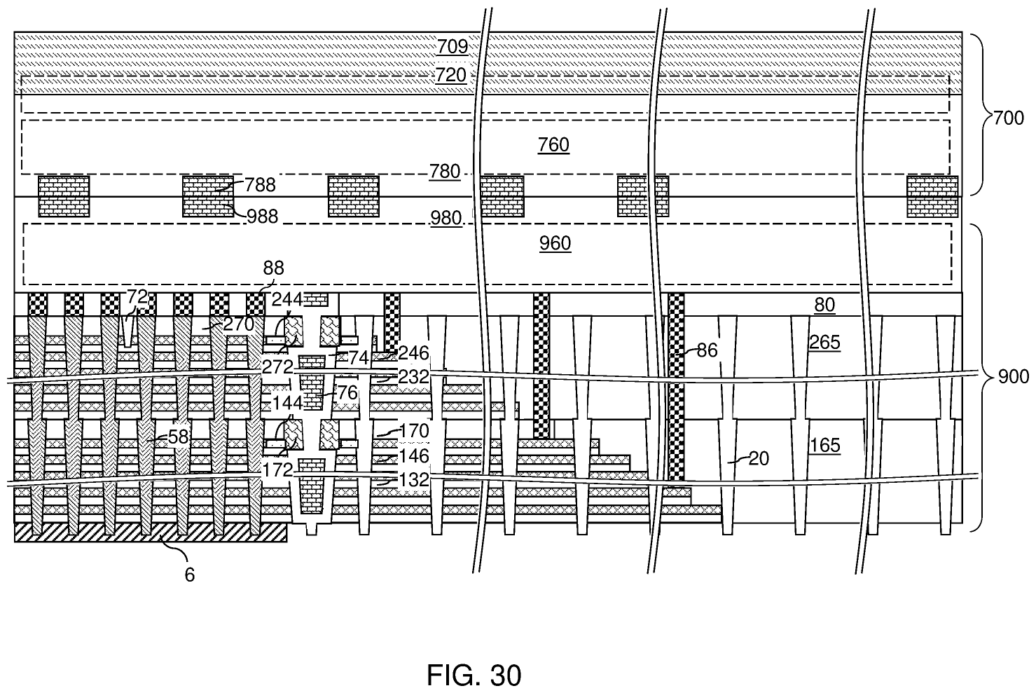

Referring to FIG. 30, a seventh alternative configuration of the exemplary structure is illustrated, which can be derived from the exemplary structure illustrated in FIG. 23 by omitting formation of the third-tier structure. In this case, the contact-level dielectric layer 80 can be formed directly on the top surface of the second insulating cap layer 270.

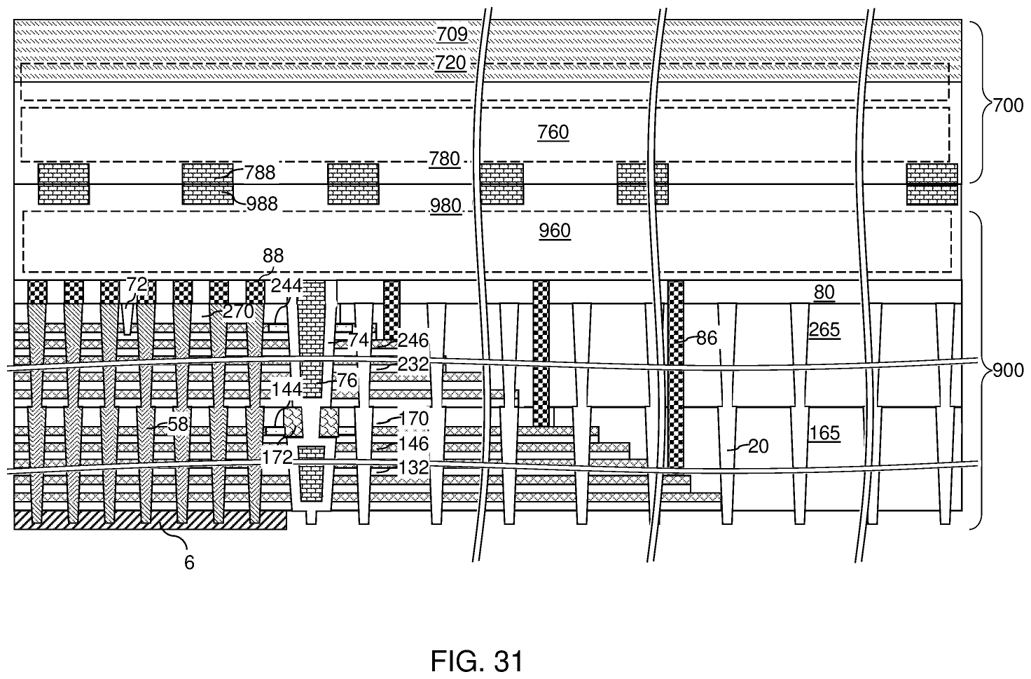

Referring to FIG. 31, an eighth alternative configuration of the exemplary structure is illustrated, which can be derived from the seventh alternative configuration of the exemplary structure illustrated in FIG. 30 by omitting formation of the second-tier bridge structures 272.

Referring to all drawings and according to various embodiments of the present disclosure, a semiconductor structure comprises: a first-tier structure including a pair of first alternating stacks (132, 146) of first insulating layers 132 and first electrically conductive layers 146; memory openings 49 vertically extending through the first-tier structure; memory opening fill structures 58 located in the memory openings, wherein each of the memory opening fill structures 58 comprises a vertical semiconductor channel 60 and a memory film 50; a lateral isolation trench (172, 79) located between the pair of first alternating stacks, and comprising a lateral isolation cavity 79 having a pair of lengthwise sidewalls that laterally extend generally along a first horizontal direction, wherein each lengthwise sidewall of the lateral isolation cavity comprises first vertically-straight and laterally-concave surface segments of the first-tier structure that are adjoined to each other at first vertically-extending edges; and a lateral isolation trench fill structure (172, 74) located in the lateral isolation trench (172, 79). The lateral isolation trench fill structure (172, 74) comprises: first-tier bridge structures 172 comprising a different material from the insulating layers 132, wherein each of the first-tier bridge structures 172 has a respective set of at least one vertically-extending perforation 72 therethrough; and an insulating spacer 74 continuously extending over sidewalls of the lateral isolation cavity 79.

In one embodiment, the first-tier bridge structures 172 comprise a semiconductor material, such as amorphous silicon or polysilicon.

In one embodiment, the insulating spacer 74 continuously extends under bottom surfaces of the first-tier bridge structures 172 and into each vertically-extending perforation 73 in the first-tier bridge structures 172. In one embodiment, the first-tier bridge structures 172 comprise lengthwise sidewalls 172L that laterally extend straight along the first horizontal direction hd1 without the laterally-concave surface segments, and widthwise sidewalls 172W that laterally extend along a second horizontal direction hd2 that is perpendicular to the first horizontal direction hd1; and the insulating spacer 74 contacts each widthwise sidewall 172W of the first-tier bridge structures 172.

In one embodiment, the semiconductor structure further comprises a second-tier structure contacting a top surface of the first-tier structure within a first horizontal plane and comprising a pair of second alternating stacks of second insulating layers 232 and second electrically conductive layers 246. The memory openings further vertically extend through the second-tier structure; the lateral isolation trench (172, 79) is also located between the pair of second alternating stacks; each lengthwise sidewall of the lateral isolation cavity 79 further comprises second vertically-straight and laterally-concave surface segments of the second-tier structure that are adjoined to each other at second vertically-extending edges; and the first-tier bridge structures 172 having a respective top surface located within the first horizontal plane.

In one embodiment, each of the memory openings 49 comprises: a first tapered sidewall vertically extending through the first-tier structure; a second tapered sidewall vertically extending through the second-tier structure; and an annular planar surface located within the first horizontal plane and having an inner periphery that is adjoined to a bottom periphery of the second tapered sidewall.

In one embodiment, the lateral isolation trench fill structure (172, 272, 74) further comprises semiconductor second-tier bridge structures 272 each having a respective set of at least one vertically-extending perforation 73 therethrough and having a respective top surface located within a second horizontal plane that includes a topmost surface of the second-tier structure.

In one embodiment, the semiconductor structure further comprises a third-tier structure contacting a top surface of the second-tier structure within a second horizontal plane and comprising a pair of third alternating stacks (332, 346) of third insulating layers 332 and third electrically conductive layers 346, wherein: the memory openings 49 also vertically extend through the third-tier structure; and the lateral isolation trench is also located between the pair of third alternating stacks (332, 346). In one embodiment, the lateral isolation trench fill structure (172, 272, 372, 74, 76) further comprises a trench fill material portion 76 filling a volume laterally bounded by the insulating spacer 74, and additional semiconductor bridge structures (such as third-tier bridge structures 372) each having a respective set of at least one vertically-extending perforation therethrough and having a respective top surface located within a third horizontal plane that includes a topmost surface of the third-tier structure.

In one embodiment, each top surface of the first-tier bridge structures 172 comprises a center portion that is contacted by the insulating spacer 74, and a pair of peripheral strip portions that are contacted by bottom surface segments of the second-tier structure. In one embodiment, points of center of curvature for a facing pair of first vertically-straight and laterally-concave surface segments of the first-tier structure are located on a vertical line that passes through a geometrical center of one of the vertically-extending perforations in the first-tier bridge structures 172.

The various embodiments of the present disclosure provide bridge structures (172, 272, 372) which provide structural support and reduce or prevent tilting and buckling of the various tiers of the alternating stacks into lateral isolation cavities 79. The embodiment methods of forming the bridge structures are simpler and less expensive than various prior art methods.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a first-tier structure including a pair of first alternating stacks of first insulating layers and first electrically conductive layers;
memory openings vertically extending through the first-tier structure;
memory opening fill structures located in the memory openings, wherein each of the memory opening fill structures comprises a vertical semiconductor channel and a memory film;
a lateral isolation trench located between the pair of first alternating stacks, and comprising a lateral isolation cavity having a pair of lengthwise sidewalls that laterally extend generally along a first horizontal direction, wherein each lengthwise sidewall of the lateral isolation cavity comprises first vertically-straight and laterally-concave surface segments of the first-tier structure that are adjoined to each other at first vertically-extending edges; and
a lateral isolation trench fill structure located in the lateral isolation trench, wherein the lateral isolation trench fill structure comprises:
first-tier bridge structures comprising a different material from the insulating layers wherein each of the first-tier bridge structures has a respective set of at least one vertically-extending perforation therethrough; and
an insulating spacer continuously extending over sidewalls of the lateral isolation cavity.

2. The semiconductor structure of claim 1, wherein the first-tier bridge structures comprise a semiconductor material.

3. The semiconductor structure of claim 2, wherein the first-tier bridge structures comprise amorphous silicon or polysilicon.

4. The semiconductor structure of claim 1, wherein the insulating spacer continuously extends under bottom surfaces of the first-tier bridge structures and into each of the vertically-extending perforations in the first-tier bridge structures.

5. The semiconductor structure of claim 1, wherein:
the first-tier bridge structures comprise lengthwise sidewalls that laterally extend straight along the first horizontal direction without the laterally-concave surface segments, and widthwise sidewalls that laterally extend along a second horizontal direction that is perpendicular to the first horizontal direction; and
the insulating spacer contacts each widthwise sidewall of the first-tier bridge structures.

6. The semiconductor structure of claim 1, further comprising a second-tier structure contacting a top surface of the first-tier structure within a first horizontal plane and comprising a pair of second alternating stacks of second insulating layers and second electrically conductive layers,
wherein:
the memory openings further vertically extend through the second-tier structure;
the lateral isolation trench is also located between the pair of second alternating stacks;
each lengthwise sidewall of the lateral isolation cavity further comprises second vertically-straight and laterally-concave surface segments of the second-tier structure that are adjoined to each other at second vertically-extending edges; and
the first-tier bridge structures having a respective top surface located within the first horizontal plane.

7. The semiconductor structure of claim 6, wherein each of the memory openings comprises:
a first tapered sidewall vertically extending through the first-tier structure;
a second tapered sidewall vertically extending through the second-tier structure; and
an annular planar surface located within the first horizontal plane and having an inner periphery that is adjoined to a bottom periphery of the second tapered sidewall.

8. The semiconductor structure of claim 6, wherein the lateral isolation trench fill structure further comprises semiconductor second-tier bridge structures each having a respective set of at least one vertically-extending perforation therethrough and having a respective top surface located within a second horizontal plane that includes a topmost surface of the second-tier structure.

9. The semiconductor structure of claim 6, further comprising a third-tier structure contacting a top surface of the second-tier structure within a second horizontal plane and comprising a pair of third alternating stacks of third insulating layers and third electrically conductive layers, wherein:
the memory openings further vertically extend through the third-tier structure; and
the lateral isolation trench is also located between the pair of third alternating stacks.

10. The semiconductor structure of claim 9, wherein the lateral isolation trench fill structure further comprises:
a trench fill material portion filling a volume laterally bounded by the insulating spacer; and
additional semiconductor bridge structures each having a respective set of at least one vertically-extending perforation therethrough and having a respective top surface located within a third horizontal plane that includes a topmost surface of the third-tier structure.

11. The semiconductor structure of claim 6, wherein each top surface of the first-tier bridge structures comprises a center portion that is contacted by the insulating spacer, and a pair of peripheral strip portions that are contacted by bottom surface segments of the second-tier structure.

12. The semiconductor structure of claim 1, wherein points of center of curvature for a facing pair of first vertically-straight and laterally-concave surface segments of the first-tier structure are located on a vertical line that passes through a geometrical center of one of the vertically-extending perforations in the first-tier bridge structures.

13. A method of forming a semiconductor structure, comprising:
forming a first alternating stack of first insulating layers and first sacrificial material layers;
forming first-tier memory openings and first-tier isolation openings through the first alternating stack;
forming first sacrificial memory opening fill structures and first-tier sacrificial isolation opening fill structures in the first-tier memory openings and in the first-tier isolation openings, respectively;
forming first-tier bridge structures around a subset of the first-tier sacrificial isolation opening fill structures;
forming a second alternating stack of second insulating layers and second sacrificial material layers over the first alternating stack;
forming second-tier memory openings and second-tier isolation openings through the second alternating stack;
removing the first sacrificial memory opening fill structures, wherein memory openings are formed within volumes of the first-tier memory openings and the second-tier memory openings;
forming memory opening fill structures in the memory openings, wherein each of the memory opening fill structure comprises a respective vertical semiconductor channel and a vertical memory film;
removing the first-tier sacrificial isolation opening fill structures, wherein inter-tier isolation openings are formed within volumes of the first-tier isolation openings and the second-tier isolation openings; and
laterally expanding the inter-tier isolation openings to form a lateral isolation cavity by performing a first isotropic etch process which isotropically etches the first alternating stack and the second alternating stack selective to the first-tier bridge structures.

14. The method of claim 13, further comprising performing a second isotropic etch process by supplying into the lateral isolation cavity an isotropic etchant that etches materials of the second sacrificial material layers and the first sacrificial material layers selective to materials of the first insulating layers, the second insulating layers, and the first-tier bridge structures to form laterally-extending cavities within volumes of the second sacrificial material layers and the first sacrificial material layer.

15. The method of claim 14, further comprising forming electrically conductive layers in the laterally-extending cavities by performing an isotropic conductive material deposition process that provides a reactant into the laterally-extending cavities through the lateral isolation cavity and deposits an electrically conductive material in the laterally-extending cavities, and by isotropically recessing the deposited electrically conductive material.

16. The method of claim 15, further comprising:
forming an insulating spacer in peripheral regions of the lateral isolation trench by performing a conformal deposition process; and
forming a trench fill material portion within a volume of the lateral isolation cavity that is not filled with the insulating spacer.

17. The method of claim 13, wherein the first-tier bridge structures contact cylindrical surface segments of the subset of the first-tier sacrificial isolation opening fill structures, and have top surfaces within a same horizontal plane as top surfaces of the first-tier sacrificial isolation opening fill structures.

18. The method of claim 13, wherein the first-tier bridge structures comprise a semiconductor material that contains vertically extending perforations.

19. The method of claim 13, further comprising:
forming second sacrificial memory opening fill structures and second sacrificial isolation opening fill structures in the second-tier memory openings and in the second-tier isolation openings, respectively; and
forming second-tier bridge structures around a subset of the second sacrificial isolation opening fill structures, wherein the first isotropic etch process is selective to the second-tier bridge structures.

20. The method of claim 13, further comprising:
forming a third alternating stack of third insulating layers and third sacrificial material layers over the second alternating stack;
forming third-tier memory openings and third-tier isolation openings through the third alternating stack; and
forming third sacrificial memory opening fill structures and third sacrificial isolation opening fill structures in the third-tier memory openings and in the third-tier isolation openings, respectively.
